(19) United States
(12) Patent Application Publication
(10) Pub. No.: US 2026/0305118 A1
(43) Pub. Date: Oct. 1, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventor: Won Sang PARK, Yongin-si (KR)

(21) Appl. No.: 19/557,887

(22) Filed: Mar. 5, 2026

(30) Foreign Application Priority Data
Mar. 27, 2025 (KR) 10-2025-0039422

(51) Int. Cl. H10K 59/65; H10K 59/121; H10K 59/40; H10K 59/80; H10K 59/88; H10K 102/10

(52) U.S. Cl. CPC H10K 59/65; H10K 59/1213; H10K 59/40; H10K 59/80517; H10K 59/80518; H10K 59/88; H10K 2102/102; H10K 2102/103

(57) ABSTRACT

A display device and an electronic device including the same. The display device includes a first display area and a second display area surrounded by the first display area. The second display area includes a second light emitting pixel, a transmission area disposed on a side of the second light emitting pixel, and a sensing pixel including a sensing pixel circuit and a light receiving element. The display device includes a substrate, a circuit layer disposed on the substrate, and an element layer disposed on the circuit layer. The light receiving element is disposed in at least one of the circuit layer or the element layer, the light receiving element of the sensing pixel overlaps the transmission area, and the sensing pixel circuit of the sensing pixel does not overlap the transmission area.

### CROSS-REFERENCE TO RELATED APPLICATION(S)

This application claims priority under 35 U.S.C. § 119 to and benefits from Korean Patent Application No. 10-2025-0039422 filed on Mar. 27, 2025 in the Korean Intellectual Property Office, the entire contents of which is herein incorporated by reference.

### TECHNICAL FIELD

The disclosure relates to a display device and an electronic device including the same.

### DISCUSSION OF THE RELATED ART

With the advance of information-oriented society, more and more demand is being placed on display devices to display images in various ways. For example, display devices are employed in various electronic devices such as smartphones, digital cameras, laptop computers, navigation devices, and smart televisions.

The display device may include various optical devices such as an image sensor for capturing an image of the front surface, a proximity sensor for detecting whether a user is positioned close to the front surface of the display device, an illuminance sensor for detecting illumination of the front surface of the display device, and an iris sensor for recognizing an iris of a user.

With diversified electronic devices employing display devices, various designs for display devices are required. For example, in the case of a smartphone, a display device with a display area increased by removing a hole disposed on the front surface of the display device is required. In other words, optical devices disposed in a hole disposed on the front surface of the display device may overlap the display panel.

### SUMMARY

Aspects of the disclosure provide a display device in which a sensor is embedded and an electronic device including the same.

According to an aspect of the disclosure, there is provided a display device including, a first display area including a first light emitting pixel including a first light emitting pixel circuit and a first light emitting element, a second display area surrounded by the first display area. The second display area including a second light emitting pixel including a second light emitting pixel circuit and a second light emitting element, a transmission area disposed on a side of the second light emitting pixel, and a sensing pixel including a sensing pixel circuit and at least one light receiving element. The display device may also include a substrate, a circuit layer disposed on the substrate, the circuit layer including the first light emitting pixel circuit, the second light emitting pixel circuit, and the sensing pixel circuit are disposed, and an element layer including the first light emitting element and the second light emitting element are disposed. The at least one light receiving element is disposed in at least one of the circuit layer or the element layer. The light receiving element of the sensing pixel overlaps the transmission area. The sensing pixel circuit of the sensing pixel does not overlap the transmission area.

In an embodiment, each of the at least one light receiving element may include a sensor electrode, a light receiving layer disposed on the sensor electrode, and a common electrode disposed on the light receiving layer, and the sensor electrode, the light receiving layer, and the common electrode may include a transparent material.

In an embodiment, the light receiving layer may include at least one of DCV5T-Me:C60, BDP-OMe:C60, or QM1:C60.

In an embodiment, the first light emitting element and the second light emitting element may include a pixel electrode, a light emitting layer disposed on the pixel electrode, and the common electrode disposed on the light emitting layer, and the pixel electrode may include an opaque electrode.

In an embodiment, the sensor electrode may include a transparent conductive layer (TCO), and the pixel electrode may include a transparent conductive layer (TCO) and a reflective layer.

In an embodiment, the transparent conductive layer may include at least one of ITO or IZO, and the reflective layer may include a silver alloy.

In an embodiment, the at least one light receiving element may include a first light receiving element comprising a first sensor electrode, and the first sensor electrode may be electrically connected to the sensing pixel circuit through a bridge electrode disposed in a different layer from the first sensor electrode.

In an embodiment, the first sensor electrode and the bridge electrode may be connected by a contact hole penetrating an insulating film, and the contact hole may be disposed in the transmission area.

In an embodiment, the bridge electrode may overlap the transmission area, and the first sensor electrode and the bridge electrode may each include transparent electrodes.

In an embodiment, the at least one light receiving element may further include a second light receiving element including a second sensor electrode, the second sensor electrode may be connected to the first sensor electrode through a bridge portion, and the first sensor electrode, the second sensor electrode, and the bridge portion may be disposed in a same layer.

In an embodiment, a density of the first light emitting pixel in the first display area may be greater than a density of the second light emitting pixel in the second display area.

In an embodiment, a density of the second light emitting pixel in the second display area may be greater than a density of the sensing pixel in the second display area.

In an embodiment, the display device may further include a non-display area disposed external to the first display area, a display driving circuit disposed in the non-display area, and a read-out line intersecting the second display area and the non-display area, wherein the sensing pixel may be connected to the display driving circuit through the read-out line.

In an embodiment, the circuit layer may include a first active layer and a second active layer in which semiconductor regions of respective transistors of the first light emitting pixel circuit and the second light emitting pixel circuit may be disposed, the light receiving element may be a light sensing transistor disposed in the circuit layer and may include a semiconductor region that receives light, and the semiconductor region of the light sensing transistor of each of the at least one light receiving element may be disposed in at least one of the first active layer or the second active layer.

In an embodiment, the display device may further include a touch sensing layer disposed on the element layer.

In an embodiment, the display device may further include a color filter layer disposed on the touch sensing layer.

In an embodiment, the second light emitting pixel and the transmission area may be disposed alternately in the second display area.

In an embodiment, the at least one light receiving element may include a plurality of light receiving elements that surround the second light emitting pixel.

In an embodiment, the second display area may further include a dummy area in an area other than the transmission area, and the second light emitting pixel and the sensing pixel circuit are not disposed in the dummy area.

According to an aspect of the disclosure, there is provided an electronic device including a display device configured to display an image, a processor configured to an image driving signal to the display device, and a power module configured to supply power to the display device and the processor. The display device includes a first display area including a first light emitting pixel including a first light emitting pixel circuit and a first light emitting element, a second display area surrounded by the first display area, the second display area including a second light emitting pixel including a second light emitting pixel circuit and a second light emitting element, a transmission area disposed on a side of the second light emitting pixel, and a sensing pixel including a sensing pixel circuit and a light receiving element. The display device also includes a substrate, a circuit layer disposed on the substrate, the circuit layer including the first light emitting pixel circuit, the second light emitting pixel circuit, and the sensing pixel circuit, and an element layer including the first light emitting element and the second light emitting element. The light receiving element is disposed in at least one of the circuit layer or the element layer. The light receiving element of the sensing pixel overlaps the transmission area. The sensing pixel circuit of the sensing pixel does not overlap the transmission area.

According to a display device and an electronic device including the same according to an embodiment of the disclosure, a sensor may be embedded in the display device.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view showing a display device according to an embodiment;

FIG. 2 is a plan view illustrating a display device according to an embodiment;

FIG. 3 is a cross-sectional view of the display device taken along line X1-X1′ of FIG. 2;

FIG. 4 is a plan view illustrating a light emitting pixel, a sensing pixel, various drivers, and various wires of a display device according to an embodiment;

FIG. 5 is a block diagram illustrating a light emitting pixel, a sensing pixel, various drivers, and various wires of a display device according to an embodiment;

FIG. 6 is a circuit diagram illustrating a light emitting pixel of a display device according to an embodiment;

FIG. 7 is a cross-sectional view illustrating a light emitting pixel of a display device according to an embodiment;

FIG. 8 is a circuit diagram of a sensing pixel of a display device according to an embodiment;

FIG. 9 is a cross-sectional view illustrating a sensing pixel of a display device according to an embodiment;

FIG. 10 is an enlarged view of area A of FIG. 2;

FIG. 11 is a plan view illustrating a main display area of a display device according to an embodiment;

FIG. 12 is a plan view illustrating a sub-display area of a display device according to an embodiment;

FIG. 13 is a cross-sectional view taken along line X2-X2′ in FIG. 12;

FIG. 14 is a cross-sectional view illustrating a stacked structure of a light emitting element of a display device and an adjacent layer thereof according to an embodiment;

FIG. 15 is a cross-sectional view illustrating a stacked structure of a light receiving element of a display device and an adjacent layer thereof according to an embodiment;

FIG. 16 is a plan view illustrating a display area of a display device according to an embodiment;

FIG. 17 is a plan view illustrating a display area of a display device according to an embodiment;

FIG. 18 is a cross-sectional view illustrating a sub-display area of a display device according to the embodiment of FIG. 17;

FIG. 19 is a cross-sectional view illustrating a sub-display area of a display device according to an embodiment;

FIG. 20 is a cross-sectional view illustrating a sub-display area of a display device according to an embodiment;

FIG. 21 is a block diagram of an electronic device according to an embodiment; and

FIG. 22 is schematic views of electronic devices according to various embodiments.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it can be on (e.g., directly on) another layer or substrate, or intervening layers may also be present. The same reference numbers indicate the same components throughout the specification. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Hereinafter, embodiments of the disclosure will be described in detail with reference to the accompanying drawings.

According to embodiments, a display device 10 in a plan view may include a sub-display area SDA surrounded by a main display area MDA, where a light receiving element PD is disposed (or embedded) in the sub-display area SDA as opposed to being external to a display panel 100. By having the light receiving element PD in the display panel 100, an external optical device 700 may not be necessary, thereby reducing manufacturing costs and resulting in a more compact design. The sub-display area SDA may include sub-display pixels SDX, transmission areas TA, and sensing areas PDA that includes the light receiving elements PD. The light receiving elements PD may be disposed in a transmission area TA. In a thickness direction, the display device may include an element layer EML where the light emitting elements are disposed and a circuit layer TFTL where the sub-pixel circuits SPC and sub-emission areas SEA including light emitting elements ED are disposed. The light receiving elements PD may be arranged in either of the element layer EML or the circuit layer TFTL depending on the embodiment. As a result, the display area DA of the display device 10 is uninterrupted as light emitting pixels PX are arranged in the sub-display area SDA, while transparent regions TA capable of transmitting external light can include the light receiving elements PD.

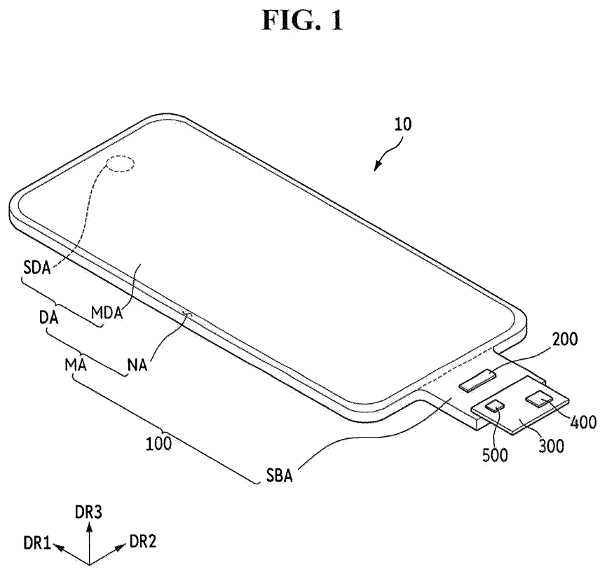

FIG. 1 is a perspective view showing a display device according to an embodiment.

Referring to FIG. 1, a display device 10, which is a device for displaying a moving image or a still image, may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). In the following, an embodiment in which the display device 10 is an organic light emitting display device is described, but the type of display device 10 is not necessarily limited thereto.

In an embodiment, the display device 10 may be formed substantially flat. For example, the display device 10 may be formed substantially flat on a plane defined by a first direction DR1 and a second direction DR2, and may have a thickness (e.g., predetermined or selectable thickness or height) in a third direction DR3. In an embodiment, the display device 10 may include a curved surface in at least a part including an edge region and the like. The display device 10 may be formed to be flexible so that it can be curved, bent, folded, or rolled.

In an embodiment, with respect to the image display surface of the display device 10, the first direction DR1 may be a lengthwise direction, a column direction, or a vertical direction, and the second direction DR2 may be a direction intersecting the first direction DR1, for example, a widthwise direction, a row direction, or a horizontal direction. The third direction DR3 may be a thickness direction or a height direction of the display device 10.

The display device 10 may include a display panel 100, a display driver 200, a circuit board 300, a touch driver 400, and a power supply unit 500.

The display panel 100 may include a main region MA including a display area DA in which an image is displayed, and a sub-region SBA located (or disposed) on a side of the main region MA.

The main region MA may include the display area DA and a non-display area NA surrounding the display area DA. The display area DA may be positioned in the center of the main region MA and occupy most of the area in the main region MA. The non-display area NA may be positioned at an edge of the main region MA and may be in contact with the sub-region SBA.

The display area DA may be an area in which pixels are arranged, and may be an area in which an image is displayed by pixels. In an embodiment, the display area DA may be further provided with sensing patterns (e.g., touch electrodes) for detecting a touch input and the like, and the display area DA may include a sensing area for detecting a touch input by the sensing patterns.

In an embodiment, the display area DA may include a long side in the first direction DR1 and a short side in the second direction DR2 and may be formed as a plane having an approximately rectangular shape. A corner portion at which the long side and the short side of the display area DA meet may be rounded or right-angled. The shape of the display area DA may be variously changed according to embodiments. For example, the display area DA may be formed in a polygonal shape other than a quadrilateral shape, a circular shape, an elliptical shape, or the like.

The display area DA may include a main display area MDA and a sub-display area SDA. The sub-display area SDA may be an area where components for adding various functions to the display device 10 are located, and the sub-display area SDA may correspond to a component area.

The non-display area NA may be located immediately around the display area DA. The non-display area NA may surround the display area DA. An embedded circuit may be located in the non-display area NA. For example, an embedded circuit including a scan driving circuit or the like may be located in the non-display area NA positioned on a side (e.g., the left side or the right side) or both sides of the display area DA.

The sub-region SBA may be located on a side of the main region MA. For example, the sub-region SBA may be a region protruding in the first direction DR1 from a side of the main region MA. For example, the sub-region SBA may protrude in the first direction DR1 from the lower end of the main region MA. In an embodiment, the sub-region SBA may have a narrower width than the main region MA. For example, with respect to the second direction DR2, the sub-region SBA may have a narrower width than the main region MA.

Wires and pads may be located in the sub-region SBA. For example, in the sub-region SBA, the wires and pads connected to the pixels and/or the embedded circuit positioned in the main region MA and to the display driver 200 and/or the circuit board 300 positioned in the sub-region SBA may be located. In describing embodiments, the term “connect” may include electrical connection and/or physical connection.

In an embodiment, the display driver 200 (e.g., the display driving circuit) may be mounted in the sub-region SBA. The circuit board 300 may be located on a part of the sub-region SBA.

The display driver 200 may include a data driving circuit to drive pixels. In an embodiment, the display driver 200 may be formed as an integrated circuit (IC) chip and located in the sub-region SBA. In an embodiment, the display driver 200 may be located on the circuit board 300 on the sub-region SBA or may be located on another circuit board connected to the display panel 100 through the circuit board 300.

The circuit board 300 may be located on a part of the sub-region SBA. For example, the circuit board 300 may be bonded on the pads positioned on a portion (e.g., a lower edge) of the sub-region SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip on film (COF), but is not necessarily limited thereto.

The touch driver 400 may be mounted on the circuit board 300. The touch driver 400 may be connected to a touch sensing unit of the display panel 100. The touch driver 400 may supply a touch driving signal to multiple touch electrodes of the touch sensing unit and may sense an amount of change in capacitance between the touch electrodes. For example, the touch driving signal may be a pulse signal having a selected frequency. The touch driver 400 may calculate whether an input is made and input coordinates based on an amount of change in capacitance between the touch electrodes. The touch driver 400 may be formed as an integrated circuit (IC).

The power supply unit 500 may be located on the circuit board 300 to supply a power voltage to the display driver 200 and the display panel 100. The power supply unit 500 may generate a driving voltage to supply it to a driving voltage line, and may generate a common voltage to supply it to a common electrode. For example, the driving voltage may be a high potential voltage for driving the light emitting element, and the common voltage may be a low potential voltage for driving the light emitting element. The power supply unit 500 may generate an initialization voltage to supply it to an initialization voltage line, generate a reference voltage to supply it to a reference voltage line, generate a bias voltage to supply it to a bias voltage line, and generate a reset voltage to supply it to a reset voltage line.

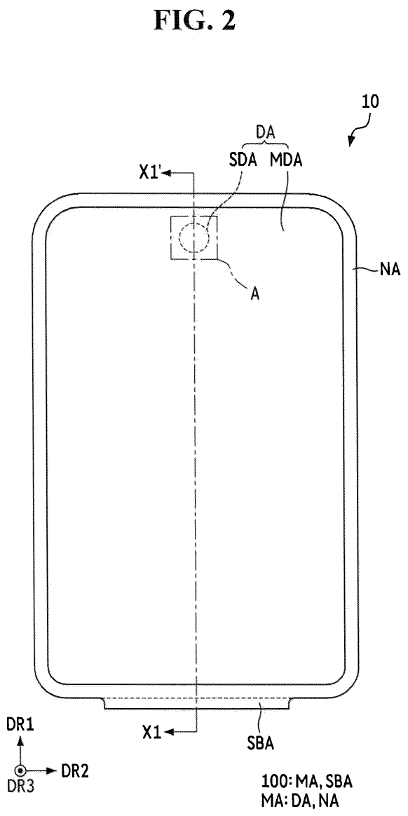

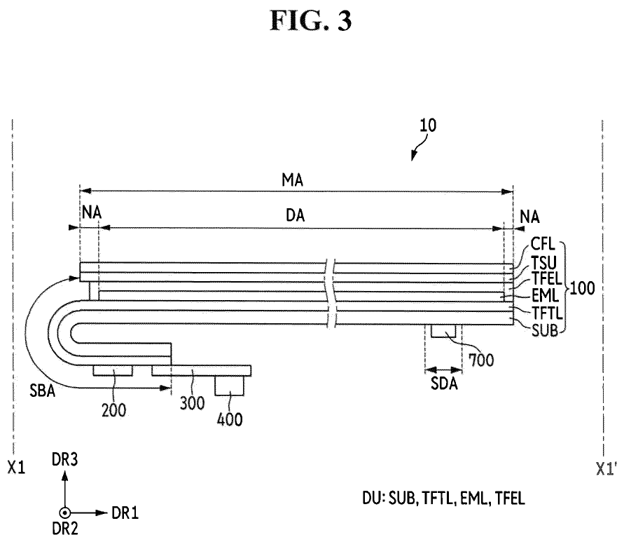

FIG. 2 is a plan view illustrating a display device according to an embodiment. FIG. 3 is a cross-sectional view of the display device taken along line X1-X1′ of FIG. 2.

Referring to FIGS. 2 and 3, the display panel 100 may include a substrate SUB including the main region MA and the sub-region SBA, and a circuit layer (or transistor layer) TFTL, an element layer EML, an encapsulation layer TFEL, a touch sensing layer TSU, and a color filter layer CFL sequentially located on the substrate SUB. The circuit layer TFTL may also be positioned in the main region MA and the sub-region SBA on the substrate SUB. The element layer EML and the encapsulation layer TFEL may be positioned on a part of the substrate SUB and the circuit layer TFTL. For example, the element layer EML and the encapsulation layer TFEL may be positioned in the main region MA.

In an embodiment, the display device 10 may further include an additional element located on the display panel 100. For example, the display device 10 may further include at least one of a polarization layer or a protective layer (e.g., a window) located on the encapsulation layer TFEL. Each of the polarization layer and/or the protective layer may be manufactured integrally with the display panel 100 or may be manufactured separately from the display panel 100 and attached to the display panel 100 through an adhesive layer or the like.

The substrate SUB may include an insulating material such as a polymer resin. For example, the substrate SUB may be made of polyimide or another insulating material. The substrate SUB may be a flexible substrate that can be transformed such as bending, folding, or rolling. For example, the substrate SUB may include an insulating material such as glass.

The circuit layer TFTL may include pixel circuits and wires. For example, the circuit layer TFTL may include circuit elements (e.g., pixel transistors and capacitors) constituting a pixel circuit for each pixel, and wires connected to the pixels. In an embodiment, the circuit layer TFTL may further include circuit elements constituting an embedded circuit, such as a scan driving circuit, and wires connected to the embedded circuit.

The element layer EML may include light emitting elements located in emission areas of the pixels. For example, each of the pixels may include at least one light emitting element and a pixel circuit connected to the light emitting element. Each of the pixels may be located in a pixel region, including the emission area where the light emitting element is located and a pixel circuit area where the pixel circuit is located. The emission area and the pixel circuit area of each pixel may overlap each other, but the disclosure is not necessarily limited thereto.

In describing the embodiments, the circuit layer TFTL and the element layer EML are separately described, but the embodiments are not necessarily limited thereto. For example, the circuit layer TFTL and the element layer EML may constitute a single uninterrupted structure.

The encapsulation layer TFEL may cover the element layer EML and may extend to the non-display area NA and contact the circuit layer TFTL. In an embodiment, the encapsulation layer TFEL may have a multilayer structure including at least two inorganic encapsulation layers overlapping each other and at least one organic encapsulation layer disposed between the inorganic encapsulation layers.

The touch sensing layer TSU may be located on the encapsulation layer TFEL. The touch sensing layer TSU may include multiple touch electrodes for sensing a user's touch in a capacitive manner, and touch lines connecting the touch electrodes to the touch driver 400. For example, the touch sensing layer TSU may sense the user's touch by using a mutual capacitance method or a self-capacitance method.

In an embodiment, the touch sensing layer TSU may be located on a separate substrate located on the display panel 100. The substrate supporting the touch sensing layer TSU may be a base that encapsulates the display panel 100.

The touch electrodes of the touch sensing layer TSU may be located in a touch sensor area overlapping the display area DA. The touch lines of the touch sensing layer TSU may be located in a touch peripheral area that overlaps the non-display area NA.

In some embodiments, the display device 10 may further include an external optical device 700. The external optical device 700 may be located in the sub-display area SDA. The external optical device 700 may emit or receive light in infrared, ultraviolet, and visible light bands. For example, the external optical device 700 may be an optical sensor that detects light incident on the display device 10 such as a proximity sensor, an illuminance sensor, and a camera sensor or an image sensor.

The color filter layer CFL may be located on the touch sensing layer TSU. The color filter layer CFL may include multiple color filters respectively corresponding to the emission areas. Each of the color filters may selectively transmit light of a specific wavelength and may block or absorb light of a different wavelength. The color filter layer CFL may absorb a part of light coming from an exterior of the display device 10 to reduce reflection of external light. Accordingly, the color filter layer CFL may prevent color distortion caused by reflection of the external light.

Since the color filter layer CFL is disposed (e.g., directly disposed) on the touch sensing layer TSU, the display device 10 might not require a separate substrate for the color filter layer CFL. Accordingly, the thickness of the display panel 100 may be small.

In an embodiment, the display panel 100 may be bent in a bending area BA. The bending area BA may be a part of the sub-region SBA and may be spaced apart from the main region MA.

The substrate SUB and the circuit layer TFTL may be bent in the bending area BA corresponding to a partial section of the sub-region SBA. Accordingly, the bezel area recognized by a user as the non-display area NA may be reduced or minimized.

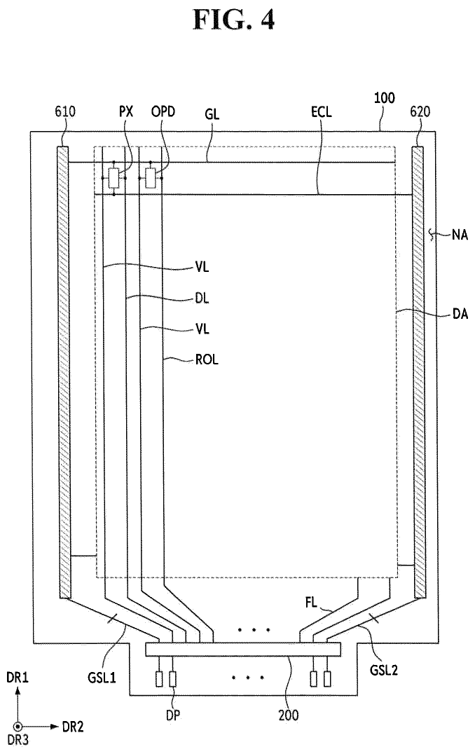

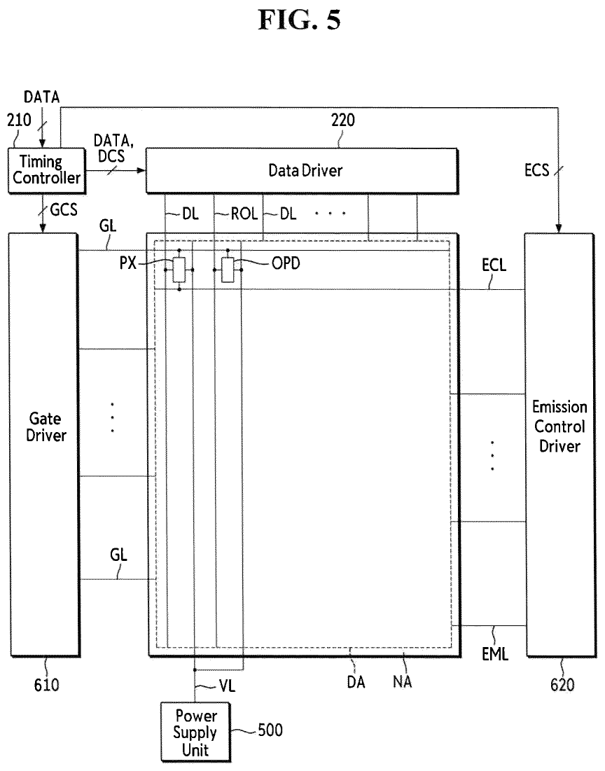

FIG. 4 is a plan view illustrating a light emitting pixel, a sensing pixel, various drivers, and various wires of a display device according to an embodiment. FIG. 5 is a block diagram illustrating a light emitting pixel, a sensing pixel, various drivers, and various wires of a display device according to an embodiment.

Referring to FIGS. 4 and 5, the display panel 100 may include the display area DA and the non-display area NA. The display area DA may include a light emitting pixel PX, a sensing pixel OPD, a power line VL, a data line DL, a read-out line ROL, a gate line GL, and an emission control line ECL.

Each of the light emitting pixels PX may be connected to the gate line GL, the emission control line ECL, the data line DL, and the power line VL. Each of the light emitting pixels PX may include multiple transistors, a light emitting element, and a capacitor.

Each of the sensing pixels OPD may be connected to the gate line GL, the power line VL, and the read-out line ROL. Each of the sensing pixels OPD may include multiple transistors and a light receiving element.

The gate lines GL may extend in the second direction DR2 and may be spaced apart from each other in the first direction DR1 intersecting the second direction DR2. The gate lines GL may sequentially supply a gate signal to the light emitting pixels PX and the sensing pixels OPD.

The emission control lines ECL may extend in the second direction DR2 and may be spaced apart from each other in the first direction DR1. The emission control lines ECL may sequentially supply an emission signal to the light emitting pixels PX.

The data lines DL may extend in the first direction DR1 and may be spaced apart from each other in the second direction DR2. The data lines DL may supply a data voltage to the light emitting pixels PX. The data voltage may determine the luminance of each of the light emitting pixels PX.

The power lines VL may extend in the first direction DR1 and may be spaced apart from each other in the second direction DR2. The power line VL may supply a power voltage to the light emitting pixels PX and the sensing pixels OPD. Here, the power voltage may be a driving voltage, a common voltage, an initialization voltage, a reference voltage, a bias voltage, or a reset voltage. The driving voltage may be a high potential voltage for driving the light emitting pixel PX, and the common voltage may be a low potential voltage for driving the light emitting pixel PX and the sensing pixel OPD.

The non-display area NA may surround the display area DA. The non-display area NA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the data line DL, supply the power voltage received from the display driver 200 to the power line VL, and supply the sensing signal received from the read-out line ROL to the display driver 200. Accordingly, the display driver 200 may drive the light emitting pixel SP and the sensing pixel OPD.

In some embodiments, the data line DL and the read-out line ROL may be located across the main display area MDA (see FIG. 1), the sub-display area SDA (see FIG. 1), and the non-display area NA (see FIG. 1).

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-region SBA may extend from a side of the non-display area NA. The sub-region SBA may include the display driver 200 and a pad portion DP. The pad portion DP may be located closer to an edge of the sub-region SBA than the display driver 200. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may generate a data control signal DCS based on the timing signals, and may supply the digital video data DATA and the data control signal DCS to the data driver 220 to control the operation timing of the data driver 220. The timing controller 210 may generate a gate control signal GCS and supply it to the gate driver 610, thus controlling the operation timing of the gate driver 610. The timing controller 210 may generate the emission control signal ECS and supply it to the emission control driver 620, thus controlling the operation timing of the emission control driver 620.

The data driver 220 may convert the digital video data DATA into analog data voltages and supply them to the data lines DL through the fan-out lines FL. The gate signals of the gate driver 610 may select the light emitting pixels PX to which the data voltage is supplied, and the selected light emitting pixels PX may receive the data voltage through the data lines DL. The data driver 220 may supply a sensing signal received through the read-out line ROL to the main processor.

The power supply unit 500 may be located on the circuit board 300 to supply a power voltage to the display driver 200 and the display panel 100. The power supply unit 500 may generate a power voltage and supply it to the power line VL, and may generate a common voltage and supply it to the common electrode that is common to the light emitting pixels PX and the sensing pixels OPD. The power supply unit 500 may generate an initialization voltage to supply it to an initialization voltage line, generate a reference voltage to supply it to a reference voltage line, generate a bias voltage to supply it to a bias voltage line, and generate a reset voltage to supply it to a reset voltage line.

The gate driver 610 may be located at an external side of the display area DA or at a side of the non-display area NA. The emission control driver 620 may be located at another external side of the display area DA or at another side of the non-display area NA. However, the disclosure is not necessarily limited thereto. As another example, the gate driver 610 and the emission control driver 620 may be located at a same side of the non-display area NA.

The gate driver 610 may include multiple transistors for generating gate signals based on the gate control signal GCS. The emission control driver 620 may include multiple transistors for generating emission signals based on the emission control signal ECS. For example, the transistors of the gate driver 610, the transistors of the emission control driver 620, and the transistors of each of the light emitting pixels PX may be disposed in a same layer. The gate driver 610 may supply the gate signals to the gate lines GL, and the emission control driver 620 may supply the emission signals to the emission control lines ECL.

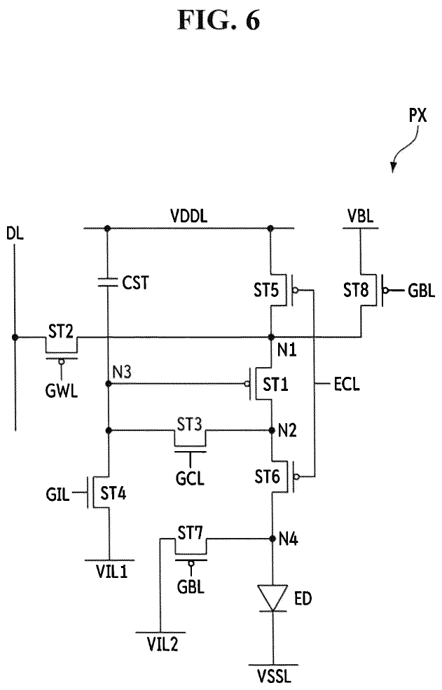

FIG. 6 is a circuit diagram illustrating a light emitting pixel of a display device according to an embodiment.

Referring to FIG. 6, the light emitting pixel PX may be connected to a first gate line GWL, a second gate line GCL, a third gate line GIL, a fourth gate line GBL, the emission control line ECL, the data line DL, a driving voltage line VDDL, a first initialization voltage line VIL1, a second initialization voltage line VIL2, a bias voltage line VBL, and a low potential line VSSL.

The light emitting pixel PX may include a light emitting element ED and a light emitting pixel circuit for driving the light emitting element ED. The light emitting pixel circuit may include first to eighth transistors ST1, ST2, ST3, ST4, ST5, ST6, ST7, and ST8 and a capacitor CST.

The first transistor ST1 may control a driving current supplied to the light emitting element ED. The first transistor ST1 may include a gate electrode, a first electrode, and a second electrode. The gate electrode of the first transistor ST1 may be connected to a third node N3, the first electrode thereof may be connected to a first node N1, and the second electrode thereof may be connected to a second node N2. For example, the first electrode of the first transistor ST1 may be a source electrode and the second electrode thereof may be a drain electrode, but the disclosure is not necessarily limited thereto.

The first transistor ST1 may control a source-drain current (hereinafter, referred to as “driving current”) Isd according to the data voltage applied to the gate electrode. The driving current flowing through the channel of the first transistor ST1 may be proportional to the square of a difference between a threshold voltage Vth and a voltage Vsg between the source electrode and the gate electrode of the first transistor ST1 (Isd=k×(Vsg−Vth)²). Here, k is a proportional coefficient determined by the structure and physical characteristics of the first transistor ST1, Vsg is a source-gate voltage of the first transistor ST1, and Vth is a threshold voltage of the first transistor ST1.

The light emitting element ED may emit light by receiving a driving current. The light emission amount or the luminance of the light emitting element ED may be proportional to the magnitude of the driving current. The light emitting element ED may include a first electrode, a second electrode, and a light emitting layer located between the first electrode and the second electrode. The first electrode of the light emitting element ED may be connected to a fourth node N4. The first electrode of the light emitting element ED may be connected to the second electrode of the sixth transistor ST6 and the first electrode of the seventh transistor ST7 through the fourth node N4. The second electrode of the light emitting element ED may be electrically connected to the low potential line VSSL. The second electrode of the light emitting element ED may receive the low potential voltage from the low potential line VSSL. For example, the first electrode of the light emitting element ED may be an anode electrode or a pixel electrode, and the second electrode thereof may be a cathode electrode or a common electrode, but the disclosure is not necessarily limited thereto.

The second transistor ST2 may be turned on by the first gate signal of the first gate line GWL to electrically connect the data line DL to the first node N1 which is the first electrode of the first transistor ST1. The second transistor ST2 may be turned on based on the first gate signal to supply the data voltage to the first node N1. The gate electrode of the second transistor ST2 may be connected to the first gate line GWL, the first electrode thereof may be connected to the data line DL, and the second electrode thereof may be connected to the first node N1. The second electrode of the second transistor ST2 may be connected to the first electrode of the first transistor ST1, the second electrode of the fifth transistor ST5, and the second electrode of the eighth transistor ST8 through the first node N1. For example, the first electrode of the second transistor ST2 may be a source electrode and the second electrode thereof may be a drain electrode, but the disclosure is not necessarily limited thereto.

The third transistor ST3 may be turned on by the second gate signal of the second gate line GCL to electrically connect the second node N2, which is the second electrode of the first transistor ST1, to the third node N3, which is the gate electrode the first transistor ST1. The gate electrode of the third transistor ST3 may be connected to the second gate line GCL, the first electrode thereof may be connected to the second node N2, and the second electrode thereof may be connected to the third node N3. The first electrode of the third transistor ST3 may be connected to the second electrode of the first transistor ST1 and the first electrode of the sixth transistor ST6 through the second node N2. The second electrode of the third transistor ST3 may be connected to the gate electrode of the first transistor ST1, the first electrode of the fourth transistor ST4, and a first capacitor electrode of the capacitor CST through the third node N3. For example, the first electrode of the third transistor ST3 may be a drain electrode and the second electrode thereof may be a source electrode, but is not necessarily limited thereto.

The fourth transistor ST4 may be turned on by a third gate signal of the third gate line GIL to electrically connect the third node N3, which is the gate electrode of the first transistor ST1, to the first initialization voltage line VIL1. The fourth transistor ST4 may be turned on based on the third gate signal, thereby discharging the gate electrode of the first transistor ST1 to a first initialization voltage. The gate electrode of the fourth transistor ST4 may be connected to the third gate line GIL, the first electrode thereof may be connected to the third node N3, and the second electrode thereof may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. For example, the first electrode of the fourth transistor ST4 may be a drain electrode and the second electrode thereof may be a source electrode, but is not necessarily limited thereto.

The fifth transistor ST5 may be turned on by an emission signal of the emission control line ECL to electrically connect the driving voltage line VDDL with the first node N1 that is the first electrode of the first transistor ST1. The gate electrode of the fifth transistor ST5 may be connected to the emission control line ECL, the first electrode thereof may be connected to the driving voltage line VDDL, and the second electrode thereof may be connected to the first node N1. The second electrode of the fifth transistor ST5 may be electrically connected to the first electrode of the first transistor ST1, the second electrode of the second transistor ST2, and the second electrode of the eighth transistor ST8 through the first node N1. For example, the first electrode of the fifth transistor ST5 may be a source electrode and the second electrode thereof may be a drain electrode, but the disclosure is not necessarily limited thereto.

The sixth transistor ST6 may be turned on by the emission signal of the emission control line ECL to electrically connect the second node N2 that is the second electrode of the first transistor ST1 with the fourth node N4 that is the first electrode of the light emitting element ED. The gate electrode of the sixth transistor ST6 may be connected to the emission control line ECL, the first electrode thereof may be connected to the second node N2, and the second electrode thereof may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light emitting element ED and the first electrode of the seventh transistor ST7 through the fourth node N4. For example, the first electrode of the sixth transistor ST6 may be a source electrode and the second electrode thereof may be a drain electrode, but the disclosure is not necessarily limited thereto.

For a case in which all of the fifth transistor ST5, the first transistor ST1, and the sixth transistor ST6 are turned on, the driving current may be supplied to the light emitting element ED.

The seventh transistor ST7 may be turned on by the fourth gate signal of the fourth gate line GBL to electrically connect the second initialization voltage line VIL2 to the fourth node N4, which is the first electrode of the light emitting element ED. By turning on the seventh transistor ST7 based on the fourth gate signal, the first electrode of the light emitting element ED may be discharged to a second initialization voltage. The gate electrode of the seventh transistor ST7 may be connected to the fourth gate line GBL, the first electrode thereof may be connected to the fourth node N4, and the second electrode thereof may be connected to the second initialization voltage line VIL2. The first electrode of the seventh transistor ST7 may be connected to the first electrode of the light emitting element ED and the second electrode of the sixth transistor ST6 through the fourth node N4. For example, the first electrode of the seventh transistor ST7 may be a source electrode and the second electrode thereof may be a drain electrode, but the disclosure is not necessarily limited thereto.

The eighth transistor ST8 may be turned on by the fourth gate signal of the fourth gate line GBL to electrically connect the bias voltage line VBL with the first node N1 that is the first electrode of the first transistor ST1. The gate electrode of the eighth transistor ST8 may be connected to the fourth gate line GBL, the first electrode thereof may be connected to the bias voltage line VBL, and the second electrode thereof may be connected to the first node N1. The second electrode of the eighth transistor ST8 may be electrically connected to the first electrode of the first transistor ST1, the second electrode of the second transistor ST2, and the second electrode of the fifth transistor ST5 through the first node N1. For example, the first electrode of the eighth transistor ST8 may be a source electrode and the second electrode thereof may be a drain electrode, but the disclosure is not necessarily limited thereto. Optionally, the eighth transistor ST8 may be omitted.

Each of the first transistor ST1, the second transistor ST2, the fifth transistor ST5, the sixth transistor ST6, the seventh transistor ST7, and the eighth transistor ST8 may include a silicon-based semiconductor region. For example, each of the first transistor ST1, the second transistor ST2, the fifth transistor ST5, the sixth transistor ST6, the seventh transistor ST7, and the eighth transistor ST8 may include a semiconductor region made of low temperature polycrystalline silicon (LTPS). The semiconductor region made of low temperature polycrystalline silicon may have high electron mobility and excellent turn-on characteristics. Accordingly, since the display device 10 includes the first transistor ST1, the second transistor ST2, the fifth transistor ST5, the sixth transistor ST6, the seventh transistor ST7, and the eighth transistor ST8 having excellent turn-on characteristics, the light emitting pixels PX can be driven stably and efficiently.

Each of the first, second, fifth, sixth, seventh, and eighth transistors ST1, ST2, ST5, ST6, ST7, and ST8 may correspond to a p-type transistor. For example, each of the first transistor ST1, the second transistor ST2, the fifth transistor ST5, the sixth transistor ST6, the seventh transistor ST7, and the eighth transistor ST8 may output a current flowing into the first electrode to the second electrode based on a gate low voltage applied to the gate electrode.

Each of the third transistor ST3 and the fourth transistor ST4 may include an oxide-based semiconductor region. For example, each of the third transistor ST3 and the fourth transistor ST4 may have a coplanar structure in which the gate electrode is located on the oxide-based semiconductor region. The transistor having the coplanar structure may have excellent leakage current characteristics and perform low frequency driving, thereby reducing power consumption. Accordingly, the display device 10 may include the third transistor ST3 and the fourth transistor ST4 having excellent leakage current characteristics, thereby preventing a leakage current from flowing in the light emitting pixel, and stably maintaining the voltage in the light emitting pixel.

Each of the third transistor ST3 and the fourth transistor ST4 may correspond to an n-type transistor. For example, each of the third transistor ST3 and the fourth transistor ST4 may output a current flowing into the first electrode to the second electrode based on a gate high voltage applied to the gate electrode.

The capacitor CST may be connected between the third node N3, which is the gate electrode of the first transistor ST1, and the driving voltage line VDDL. For example, the first capacitor electrode of the capacitor CST may be connected to the third node N3, and the second capacitor electrode of the capacitor CST may be connected to the driving voltage line VDDL, thereby maintaining a potential difference between the driving voltage line VDDL and the gate electrode of the first transistor ST1.

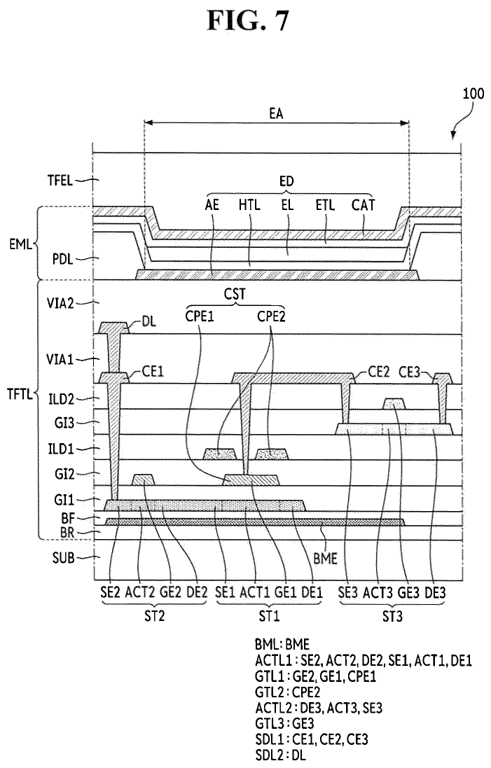

FIG. 7 is a cross-sectional view illustrating a light emitting pixel of a display device according to an embodiment.

Referring to FIG. 7 in addition to FIG. 6, the display panel 100 may include the substrate SUB, the circuit layer TFTL, the element layer EML, and the encapsulation layer TFEL. The light emitting pixel PX may include the light emitting pixel circuit and the light emitting element ED. The light emitting pixel circuit may be located in the circuit layer TFTL, and the light emitting element ED may be located in the element layer EML.

The substrate SUB may be a base substrate or a base. The substrate SUB may be a flexible substrate which can be bent, folded or rolled. For example, the substrate SUB may include a polymer resin such as polyimide, but is not necessarily limited thereto. For another example, the substrate SUB may include a glass material or a metal material.

The circuit layer TFTL may include a barrier layer BR, a lower conductive layer BML, a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, and a second via layer VIA2.

The barrier layer BR may be located on the substrate SUB. For example, the barrier layer BR may be located on the entire surface of the substrate SUB. The barrier layer BR may be a layer for protecting transistors of the circuit layer TFTL and a light emitting layer EL of the element layer EML from moisture permeating through the substrate SUB which is susceptible to moisture permeation. The barrier layer BR may include multiple inorganic films that may be alternately stacked. For example, the barrier layer BR may be a single film or multiple films in which one or more inorganic films of a silicon nitride layer, a silicon oxynitride layer, a silicon oxide layer, a titanium oxide layer and an aluminum oxide layer are alternately stacked.

The lower conductive layer BML may be located on the barrier layer BR. The lower conductive layer BML may include a lower conductive pattern BME that overlaps the semiconductor regions ACT1 and ACT2 of the first transistor ST1 and the second transistor ST2 in the third direction DR3 to prevent leakage current from occurring due to light incident on the first active layer ACTL1. The lower conductive layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. The lower conductive layer BML may be omitted.

The buffer layer BF may be located on the lower conductive layer BML. The buffer layer BF may include an inorganic layer capable of preventing permeation of air or moisture. The buffer layer BF may include multiple inorganic layers that are alternately stacked. For example, the buffer layer BF may be a single film or multiple films in which one or more inorganic films of a silicon nitride layer, a silicon oxynitride layer, a silicon oxide layer, a titanium oxide layer and an aluminum oxide layer are alternately stacked.

The first active layer ACTL1 may be located on the buffer layer BF. The first active layer ACTL1 may include a silicon-based material. For example, the first active layer ACTL1 may include low temperature polycrystalline silicon (LTPS). The first active layer ACTL1 may include the semiconductor region ACT1, the first electrode SE1, and the second electrode DE1 of the first transistor ST1, and the semiconductor region ACT2, the first electrode SE2, and the second electrode DE2 of the second transistor ST2.

The first gate insulating layer GI1 may be located on the first active layer ACTL1. The first gate insulating layer GI1 may insulate the first active layer ACTL1 from the first gate layer GTL1.

The first gate layer GTL1 may be located on the first gate insulating layer GI1. The first gate layer GTL1 may include the gate electrode GE1 of the first transistor ST1, the gate electrode GE2 of the second transistor ST2, and the first capacitor electrode CPE1. The gate electrode GE1 of the first transistor ST1 may be a part of the first capacitor electrode CPE1, and the gate electrode GE2 of the second transistor ST2 may be a part of the first gate line GWL.

The second gate insulating layer GI2 may be located on the first gate layer GTL1. The second gate insulating layer GI2 may insulate the first gate layer GTL1 from the second gate layer GTL2.

The second gate layer GTL2 may be located on the second gate insulating layer GI2. The second gate layer GTL2 may include a second capacitor electrode CPE2. The second capacitor electrode CPE2 may overlap the first capacitor electrode CPE1.

The first interlayer insulating layer ILD1 may be located on the second gate layer GTL2. The first interlayer insulating layer ILD1 may insulate the second gate layer GTL2 from the second active layer ACTL2.

The second active layer ACTL2 may be located on the first interlayer insulating layer ILD1. The second active layer ACTL2 may include an oxide-based material. The second active layer ACTL2 may include the semiconductor region ACT3, the first electrode DE3, and the second electrode SE3 of the third transistor ST3.

The third gate insulating layer GI3 may be located on the second active layer ACTL2. The third gate insulating layer GI3 may insulate the second active layer ACTL2 from the third gate layer GTL3.

The third gate layer GTL3 may be located on the third gate insulating layer GI3. The third gate layer GTL3 may include a gate electrode GE3 of the third transistor ST3. The gate electrode GE3 of the third transistor ST3 may be a part of the second gate line GCL.

The second interlayer insulating layer ILD2 may be located on the third gate layer GTL3. The second interlayer insulating layer ILD2 may insulate the third gate layer GTL3 from the first source metal layer SDL1.

The first source metal layer SDL1 may be located on the second interlayer insulating layer ILD2. The first source metal layer SDL1 may include first to third connection electrodes CE1, CE2, and CE3. The first connection electrode CE1 may electrically connect the data line DL to the first electrode SE2 of the second transistor ST2. The second connection electrode CE2 may electrically connect the first capacitor electrode CPE1 to the second electrode SE3 of the third transistor ST3. The third connection electrode CE3 may electrically connect the first electrode DE3 of the third transistor ST3 to the second electrode DE1 of the first transistor ST1.

The first via layer VIA1 may be located on the first source metal layer SDL1. The first via layer VIA1 may insulate the first source metal layer SDL1 from the second source metal layer SDL2. The top surface of the first via layer VIA1 may be substantially flat. The first via layer VIA1 may contain an organic insulating material such as polyimide (PI).

The second source metal layer SDL2 may be located on the first via layer VIA1. The second source metal layer SDL2 may include the data line DL.

The second via layer VIA2 may be located on the second source metal layer SDL2. The second via layer VIA2 may insulate the second source metal layer SDL2 from a pixel electrode AE. The top surface of the second via layer VIA2 may be substantially flat. The second via layer VIA2 may contain an organic insulating material such as polyimide (PI).

The element layer EML may include a pixel defining film PDL and the light emitting element ED.

The pixel defining film PDL may be located on the second via layer VIA2. The pixel defining film PDL may define multiple emission areas EA. The pixel defining film PDL may include an organic insulating material such as polyimide (PI), but is not necessarily limited thereto.

The light emitting element ED may include the pixel electrode AE, the hole transporting layer HTL, the light emitting layer EL, the electron transporting layer ETL, and the common electrode CAT. The pixel electrode AE may be located on the second via layer VIA2. The pixel electrode AE may overlap one of the emission areas EA defined by the pixel defining film PDL. The pixel electrode AE may receive a driving current from the pixel circuit of the light emitting pixel PX.

The hole transporting layer HTL may be located on the pixel electrode AE in the emission area EA and may be located on the pixel defining film PDL in an area other than the emission area EA. The hole transporting layer HTL may be implemented as a common layer for all the light emitting pixels PX and the sensing pixels OPD, rather than being divided for each light emitting pixel PX.

The light emitting layer EL may be located on the hole transporting layer HTL in the emission area EA. For example, the light emitting layer EL may be an organic light emitting layer made of an organic material, but is not necessarily limited thereto.

The electron transporting layer ETL may be located on the light emitting layer EL in the emission area EA and may be located on the hole transporting layer HTL in an area other than the emission area EA. The electron transporting layer ETL may be implemented as a common layer for all the light emitting pixels PX and the sensing pixels OPD, rather than being divided for each light emitting pixel PX.

The common electrode CAT may be located on the electron transporting layer ETL. For example, the common electrode CAT may be implemented in the form of an electrode that is common to all the light emitting pixels PX and the sensing pixels OPD, rather than being divided for each of the light emitting pixels PX. The common electrode CAT may be a transparent electrode and may allow light to pass through the common electrode CAT. The common electrode CAT may be electrically connected to the low potential line VSSL and may receive a low potential voltage, a common voltage, or a cathode voltage.

In the case where the light emitting layer EL corresponds to an organic light emitting layer, when a voltage (e.g., predetermined or selectable voltage) is applied to the pixel electrode AE in the pixel circuit of the light emitting pixel PX, and the common electrode CAT receives a common voltage or a cathode voltage, holes may move to the light emitting layer EL through the hole transporting layer HTL, electrons may move to the light emitting layer EL through the electron transporting layer ETL, and the holes and the electrons may combine with each other in the light emitting layer EL to emit light.

The encapsulation layer TFEL may be located on the common electrode CAT to cover the light emitting elements ED. The encapsulation layer TFEL may include at least one inorganic film to prevent oxygen or moisture from permeating into the light emitting elements ED. The encapsulation layer TFEL may include at least one organic film to protect the light emitting elements ED from foreign material such as dust.

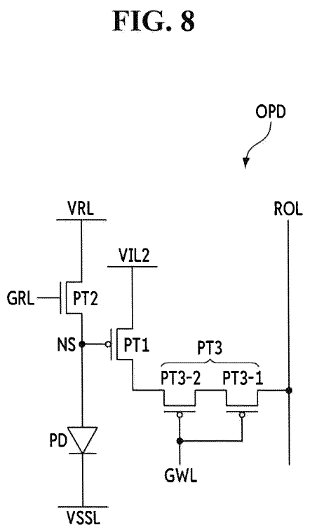

FIG. 8 is a circuit diagram of a sensing pixel of a display device according to an embodiment.

Referring to FIG. 8, the sensing pixel OPD may be connected to the first gate line GWL, the reset signal line GRL, the reset voltage line VRL, the second initialization voltage line VIL2, the low potential line VSSL, and the read-out line ROL.

The sensing pixel OPD may include a light receiving element PD and a sensing pixel circuit for driving the light receiving element PD. The sensing pixel circuit may include first to third sensor transistors PT1, PT2, and PT3.

The first sensor transistor PT1 may include a gate electrode, a first electrode, and a second electrode. The gate electrode of the first sensor transistor PT1 may be connected to the sensor node NS, the first electrode thereof may be connected to the third sensor transistor PT3, and the second electrode thereof may be connected to the second initialization voltage line VIL2. The first sensor transistor PT1 may control the source-drain current (hereinafter referred to as “sensing current”) based on the voltage of the sensor node NS, which is the first electrode of the light receiving element PD. The sensing current Isd flowing through the channel of the first sensor transistor PT1 may be proportional to the square of a difference between the threshold voltage Vth and the voltage Vsg between the source electrode and the gate electrode of the first sensor transistor PT1 (Isd=k′×(Vsg−Vth)²). Here, k′ is a proportional coefficient determined by the structure and physical characteristics of the first sensor transistor PT1, Vsg is a source-gate voltage of the first sensor transistor PT1, and Vth is a threshold voltage of the first sensor transistor PT1. The first electrode of the first sensor transistor PT1 may be a source electrode and the second electrode thereof may be a drain electrode, but the disclosure is not necessarily limited thereto.

The second sensor transistor PT2 may be turned on by the reset signal of the reset signal line GRL, thereby discharging the voltage of the sensor node NS to the reset voltage. The gate electrode of the second sensor transistor PT2 may be connected to the reset signal line GRL, the first electrode thereof may be connected to the sensor node NS, and the second electrode thereof may be connected to the reset voltage line VRL. The first electrode of the second sensor transistor PT2 may be connected to the first electrode of the light receiving element PD and the gate electrode of the first sensor transistor PT1 through the sensor node NS. The first electrode of the second sensor transistor PT2 may be a drain electrode and the second electrode thereof may be a source electrode, but is not necessarily limited thereto.

The third sensor transistor PT3 may be turned on by the first gate signal of the first gate line GWL to electrically connect the first electrode of the first sensor transistor PT1 to the read-out line ROL. The third sensor transistor PT3 may include a third-first sensor transistor PT3-1 and a third-second sensor transistor PT3-2 connected in series. The third-first sensor transistor PT3-1 and the third-second sensor transistor PT3-2 may be connected in series between the first electrode of the first sensor transistor PT1 and the read-out line ROL. The gate electrode of the third-first sensor transistor PT3-1, the gate electrode of the third-second sensor transistor PT3-2, and the first gate line GWL may form a single uninterrupted structure. The first electrode of the third-first sensor transistor PT3-1 may be connected to the read-out line ROL, and the second electrode of the third-second sensor transistor PT3-2 may be connected to the first electrode of the first sensor transistor PT1. The second electrode of the third-first sensor transistor PT3-1 and the first electrode of the third-second sensor transistor PT3-2 may constitute a single, uninterrupted structure. The first electrode of each of the third-first sensor transistor PT3-1 and the third-second sensor transistor PT3-2 may be a source electrode and the second electrode thereof may be a drain electrode, but the disclosure is not necessarily limited thereto.

The light receiving element PD may receive light and convert light energy into an electrical signal. The first electrode of the light receiving element PD may be connected to the sensor node NS, which is the gate electrode of the first sensor transistor PT1, and the second electrode thereof may be connected to the low potential line VSSL. The second electrode of the light receiving element PD may receive the low potential voltage from the low potential line VSSL. For example, the first electrode of the light receiving element PD may be a sensor electrode, and the second electrode thereof may be a common electrode, but the disclosure is not necessarily limited thereto.

For a case in which the object is positioned above the display panel 100, light emitted from the light emitting element may be reflected by the object, and the light receiving element PD may receive the reflected light. The light receiving element PD may convert the energy of light into an electrical signal (current or voltage) formed between the first and second electrodes, and the converted electrical signal may flow from the low potential line VSSL to the sensor node NS as a reverse bias current. For example, when the light receiving element PD receives light and an electric field is formed between the first and second electrodes of the light receiving element PD, a current may flow through the light receiving element PD in proportion to the amount of light and the voltage at the sensor node NS may increase. Accordingly, when the light receiving element PD receives light, the voltage of the sensor node NS may increase and the magnitude of a sensing current (or source-drain current) of the first sensor transistor PT1 may decrease. The sensing current of the first sensor transistor PT1 may be applied to the display driver 200 as a sensing signal through the third sensor transistor PT3 and the read-out line ROL.

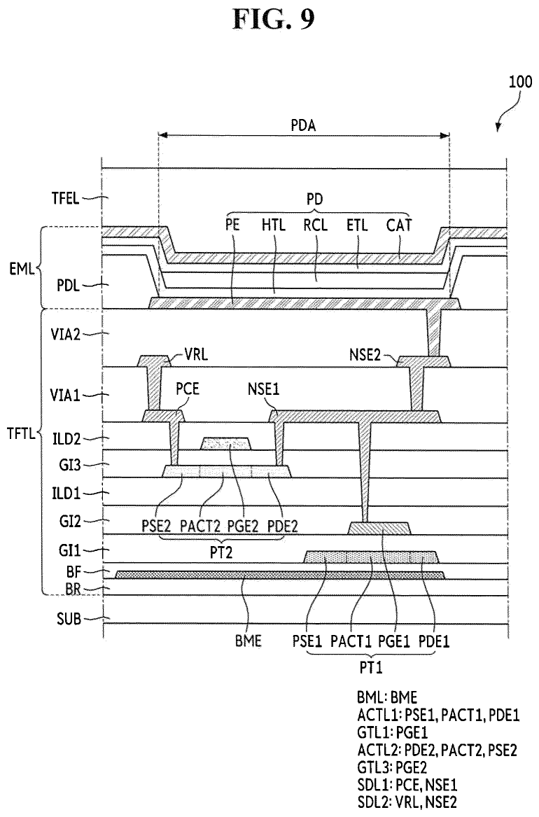

FIG. 9 is a cross-sectional view illustrating a sensing pixel of a display device according to an embodiment.

Referring to FIG. 9 in addition to FIG. 8, the display panel 100 may include the substrate SUB, the circuit layer TFTL, the element layer EML, and the encapsulation layer TFEL. The sensing pixel OPD may include the sensing pixel circuit and the light receiving element PD. The sensing pixel circuit may be located in the circuit layer TFTL, and the light receiving element PD may be located in the element layer EML.

To the extent that the substrate SUB and the encapsulation layer TFEL have not been described in detail with respect to FIG. 8, it may be understood that the substrate SUB and the encapsulation layer TFEL are at least similar to corresponding elements that have been previously described with reference to FIG. 7.

The circuit layer TFTL may include the barrier layer BR, the lower conductive layer BML, the buffer layer BF, the first active layer ACTL1, the first gate insulating layer GI1, the first gate layer GTL1, the second gate insulating layer GI2, the first interlayer insulating layer ILD1, the second active layer ACTL2, the third gate insulating layer GI3, the third gate layer GTL3, the second interlayer insulating layer ILD2, the first source metal layer SDL1, the first via layer VIA1, the second source metal layer SDL2, and the second via layer VIA2.

To the extent that the barrier layer BR, the lower conductive layer BML, the buffer layer BF, the first gate insulating layer GI1, the second gate insulating layer GI2, the first interlayer insulating layer ILD1, the third gate insulating layer GI3, the second interlayer insulating layer ILD2, the first via layer VIA1, and the second via layer VIA2 of the circuit layer TFTL have been previously described in detail with respect to FIG. 8, it may be understood that these elements are at least similar to corresponding elements that have been previously described with reference to FIG. 7.

The first active layer ACTL1 may be located on the buffer layer BF. The first active layer ACTL1 may include a silicon-based material. For example, the first active layer ACTL1 may include low temperature polycrystalline silicon (LTPS). The first active layer ACTL1 may include a semiconductor region PACT1, a first electrode PSE1, and a second electrode PDE1 of the first sensor transistor PT1.

The first gate layer GTL1 may be located on the first gate insulating layer GI1. The first gate layer GTL1 may include a gate electrode PGE1 of the first sensor transistor PT1.

The second active layer ACTL2 may be located on the first interlayer insulating layer ILD1. The second active layer ACTL2 may include an oxide-based material. The second active layer ACTL2 may include a semiconductor region PACT2, a first electrode PDE2, and a second electrode PSE2 of the second sensor transistor PT2.

The third gate layer GTL3 may be located on the third gate insulating layer GI3. The third gate layer GTL3 may include a gate electrode PGE2 of the second sensor transistor PT2. The gate electrode PGE2 of the second sensor transistor PT2 may be a portion of the reset signal line GRL.

The first source metal layer SDL1 may be located on the second interlayer insulating layer ILD2. The first source metal layer SDL1 may include a sensor connection electrode PCE and a first sensor node electrode NSE1. The sensor connection electrode PCE may electrically connect the reset voltage line VRL to the second electrode PSE2 of the second sensor transistor PT2. The first sensor node electrode NSE1 may electrically connect the first electrode PDE2 of the second sensor transistor PT2 to the gate electrode PGE1 of the first sensor transistor PT1.

The second source metal layer SDL2 may be located on the first via layer VIA1. The second source metal layer SDL2 may include the reset voltage line VRL and a second sensor node electrode NSE2. The second sensor node electrode NSE2 may electrically connect a sensor electrode PE to the first sensor node electrode NSE1.

The light receiving element PD may include the sensor electrode PE, the hole transporting layer HTL, the light receiving layer RCL, the electron transporting layer ETL, and the common electrode CAT. The sensor electrode PE may be located on the second via layer VIA2, The sensor electrode PE and the pixel electrode AE of the light emitting element ED may be disposed in a same layer. The sensor electrode PE may overlap one of multiple sensing areas PDA defined by the pixel defining film PDL.

The hole transporting layer HTL may be located on the sensor electrode PE in the sensing area PDA and may be located on the pixel defining film PDL in an area other than the sensing area PDA. The hole transporting layer HTL may be implemented as a common layer for all the light emitting pixels PX and the sensing pixels OPD, rather than being divided for each sensing pixel OPD.

The light receiving layer RCL may be located on the hole transporting layer HTL. The light receiving layer RCL may receive light emitted from the emission area EA and reflected by the object. The light emitted from the light emitting element ED of the emission area EA may be reflected by the object, and the reflected light may reach the light receiving layer RCL. The light receiving element PD may convert the energy of light into an electrical signal (current or voltage) formed between the sensor electrode PE and the common electrode CAT, and the converted electrical signal may flow to the sensor node NS of FIG. 8 as a reverse bias current. For example, when the light receiving element PD receives light and an electric field is formed between the common electrode CAT and the sensor electrode PE of the light receiving element PD, a current may flow through the light receiving element PD in proportion to the amount of light.

The electron transporting layer ETL may be located on the light receiving layer RCL in the sensing area PDA and may be located on the hole transporting layer HTL in an area other than the sensing area PDA. The electron transporting layer ETL may be implemented as a common layer for all the light emitting pixels PX and the sensing pixels OPD, rather than being divided for each sensing pixel OPD.

The common electrode CAT may be located on the electron transporting layer ETL. For example, the common electrode CAT may be implemented in the form of an electrode that is common to all the light emitting pixels PX and the sensing pixels OPD, rather than being divided for each of the light emitting pixels PX. The common electrode CAT may be a transparent electrode and may allow light to pass therethrough. The common electrode CAT may be electrically connected to the low potential line VSSL and may receive a low potential voltage, a common voltage, or a cathode voltage.

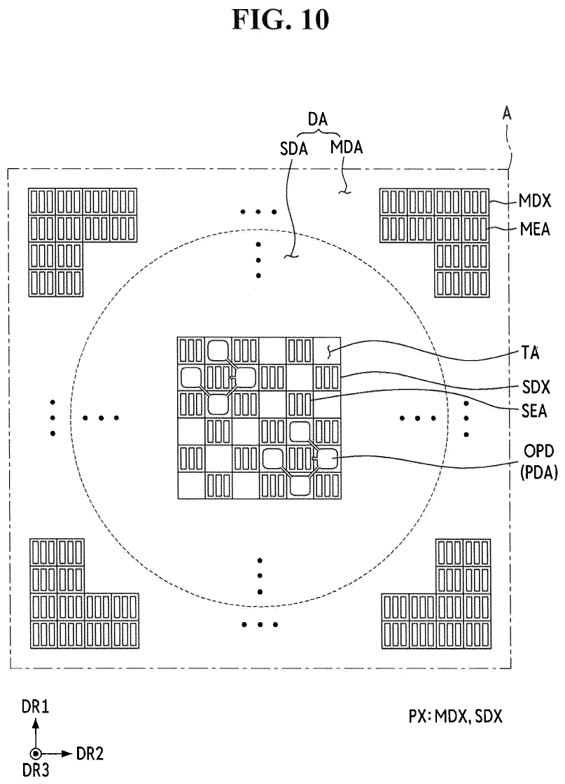

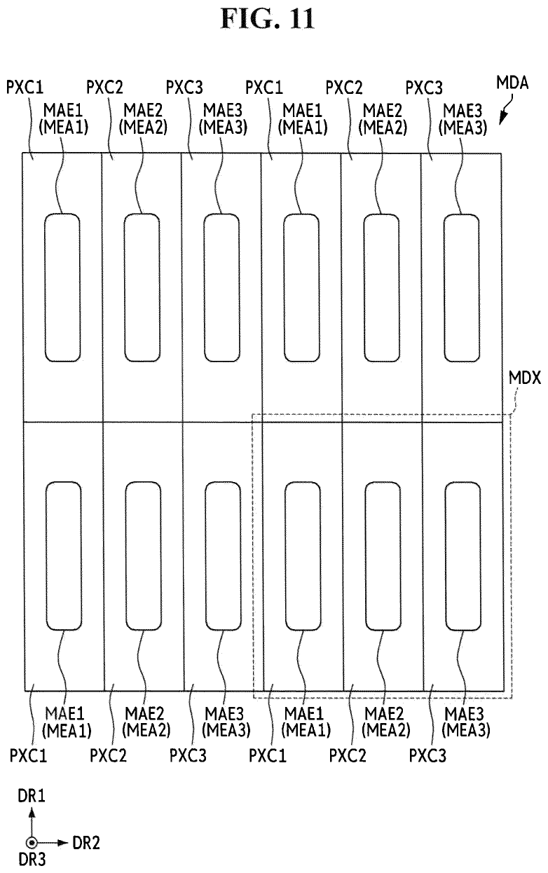

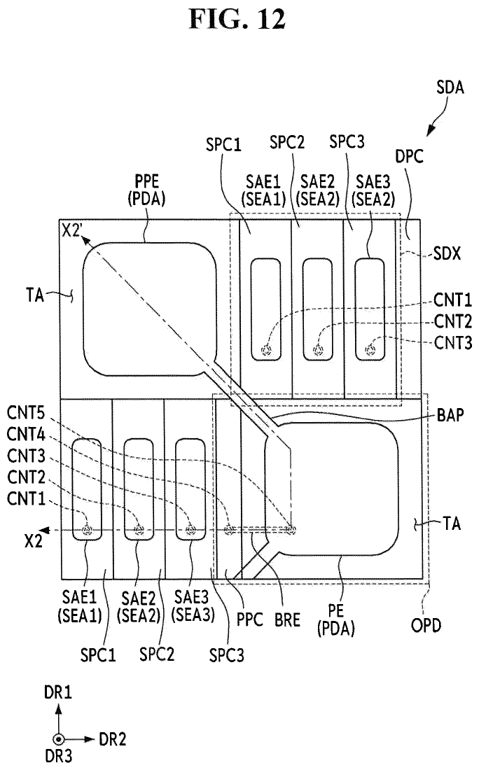

FIG. 10 is an enlarged view of area A of FIG. 2. FIG. 11 is a plan view illustrating a main display area of a display device according to an embodiment. FIG. 12 is a plan view illustrating a sub-display area of a display device according to an embodiment.

Referring to FIGS. 10 to 12 in addition to FIGS. 3, 7 and 9, the display area DA may include the main display area MDA and the sub-display area SDA. The sub-display area SDA may be an area where components are located under the substrate SUB of the display device 10.

The light emitting pixels PX may include main display pixels MDX arranged in the main display area MDA and sub-display pixels SDX arranged in the sub-display area SDA. For example, multiple main display pixels MDX may be arranged in the main display area MDA, and multiple sub-display pixels SDX may be arranged in the sub-display area SDA. Each of the main display pixels MDX may include one or more main emission areas MEA, and each of the sub-display pixels SDX may include one or more sub-emission areas SEA. A light emitting element ED may be located in each of the emission areas MEA and SEA to emit light.

Multiple light emitting elements ED that emit light, and light emitting pixel circuits that are electrically connected to the light emitting element ED and apply a signal for light emission of the light emitting element ED may be located in the main display area MDA. The main display area MDA may be an area where the light emitting elements ED and the light emitting pixel circuits are arranged in specific arrangement. In the main display area MDA, each of the light emitting elements ED may constitute the main emission area MEA, and multiple main emission areas MEA may constitute a main display pixel (e.g., single main display) MDX. For example, three main emission areas MEA may constitute a main display pixel (e.g., single main display) MDX. For example, a main display pixel (e.g., single main display) MDX may include three main emission areas MEA, and the three main emission areas MEA may constitute a main display pixel MDX to express a white grayscale.

The main display pixels MDX located in the main display area MDA may be arranged in the first direction DR1 and the second direction DR2. The main emission areas MEA of each of the main display pixels MDX may be arranged in the second direction DR2.

The main display pixel MDX may include multiple main pixel electrodes MAE1, MAE2, and MAE3. The main pixel electrodes MAE1, MAE2, and MAE3 may be anode electrodes of the light emitting elements ED that emit light of different colors. For example, the first main pixel electrode MAE1, which is the anode electrode of the light emitting element that emits light of the first color, may be located in a first main emission area MEA1. The second main pixel electrode MAE2 may be an anode electrode of a light emitting element that emits light of a second color and be located in the second main emission area MEA2, and the third main pixel electrode MAE3 may be an anode electrode of a light emitting element that emits light of a third color and be located in the third main emission area MEA3.

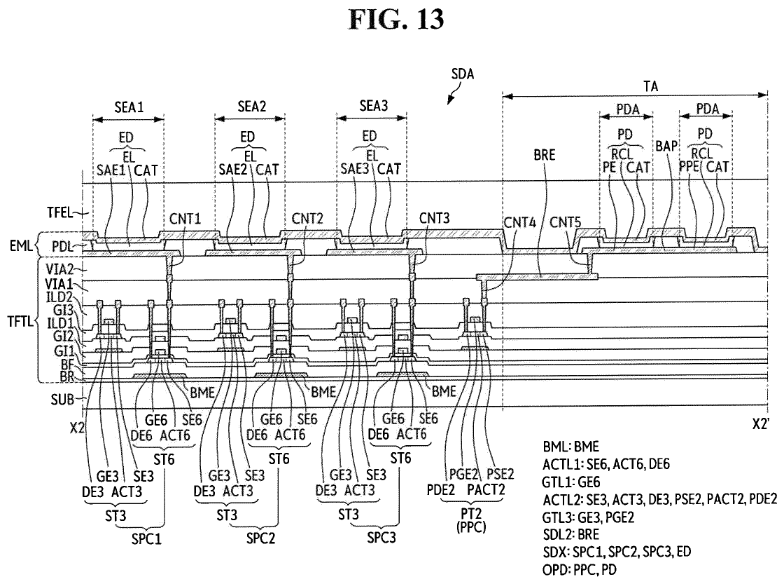

In an example embodiment, the first main emission area MEA1 may emit first light of a red color, the second main emission area MEA2 may emit second light of a green color, and the third main emission area MEA3 may emit third light of a blue color. However, the disclosure is not necessarily limited thereto. The main emission areas may be respectively defined by the openings formed in the pixel defining film PDL (see FIG. 13) of the element layer EML to be described later.

The number of main emission areas MEA included in the main display pixel MDX, the arrangement of the main display pixels MDX, and the arrangement of the main emission areas MEA are merely examples and may be modified in various ways.

Multiple main pixel circuits PXC1, PXC2, and PXC3 located in the main display area MDA may each correspond to a main pixel electrode (e.g., single main pixel electrode) MAE1, MAE2, MAE3 and a main emission area (e.g., single main emission area) MEA1, MEA2, MEA3. For example, the first main pixel circuit PXC1 may correspond to one first main pixel electrode MAE1 and be electrically connected to the first main pixel electrode MAE1. The second main pixel circuit PXC2 may correspond to one second main pixel electrode MAE2 and be electrically connected to the second main pixel electrode MAE2, and the third main pixel circuit PXC3 may correspond to one third main pixel electrode MAE3 and be electrically connected to the third main pixel electrode MAE3. The main display pixel MDX including the three main pixel electrodes MAE1, MAE2, and MAE3 may include the three main pixel circuits PXC1, PXC2, and PXC3.

The light emitting elements ED that emit light and light emitting pixel circuits that are electrically connected to the light emitting elements ED and apply signals for emitting light to the light emitting elements ED may be located in the sub-display area SDA. The sub-display area SDA may be an area where the light emitting elements ED and the light emitting pixel circuits are arranged in specific arrangement. In the sub-display area SDA, each of the light emitting elements ED may constitute the sub-emission area SEA, and multiple sub-emission areas SEA may constitute one sub-display pixel SDX. For example, three sub-emission areas SEA may constitute one sub-display pixel SDX. For example, a sub-display pixel (e.g., single sub-display pixel) SDX may include three sub-emission areas SEA, and the three sub-emission areas SEA may constitute a sub-display pixel (e.g., single sub-display pixel) SDX to express a white grayscale.

The sub-display pixel SDX may include multiple sub-pixel electrodes of SAE1, SAE2, and SAE3. The sub-pixel electrodes SAE1, SAE2, and SAE3 may be anode electrodes of the light emitting elements ED that emit light of different colors. For example, the first sub-pixel electrode SAE1, which is the anode electrode of the light emitting element that emits light of the first color, may be located in a first sub-emission area SEA1. The second sub-pixel electrode SAE2 may be an anode electrode of a light emitting element that emits light of the second color and be located in the second sub-emission area SEA2, and the third sub-pixel electrode SAE3 may be an anode electrode of a light emitting element that emits light of the third color and be located in the third sub-emission area SEA3. Multiple sub-emission areas SEA of each of the sub-display pixels SDX may be arranged in the second direction DR2.

In an example embodiment, the first sub-emission area SEA1 may emit first light of a red color, the second sub-emission area SEA 2 may emit second light of a green color, and the third sub-emission area SEA 3 may emit third light of a blue color. However, the disclosure is not necessarily limited thereto. The sub-emission areas may be respectively defined by the openings formed in the pixel defining film PDL (see FIG. 13) of the element layer EML to be described later.

The number of sub-emission areas SEA included in the sub-display pixel SDX, the arrangement of the sub-display pixels SDX, and the arrangement of the sub-emission areas SEA are merely examples and may be modified in various ways.

The sub-display pixel SDX formed by the sub-emission areas SEA of the sub-display area SDA may have an arrangement that is the same as or different from that of the main display pixel MDX. For example, the size and shape of the sub-emission areas SEA included in the sub-display pixel SDX may be substantially equal to or different from the size and shape of the main emission area MEA included in the main display pixel MDX.

The sub-display area SDA may be an area that overlaps a component, for example, the external optical device 700, located on the back surface of the substrate SUB of the display panel 100, and may have a structure in which transmittance of light is considered, unlike the main display area MDA.

For example, the sub-display area SDA may further include transmission areas TA that transmit light. The transmission area TA is an area through which light incident on the display panel 100 passes. The transmission area TA is an area having transmittance higher than the transmittance of the area where the sub-display pixel SPX is located. The transmission area TA located in the sub-display area SDA may be arranged alternately with multiple sub-display pixels SDX in the first direction DR1 and the second direction DR2.

Since the sub-display area SDA includes the transmission area TA, the density of the sub-display pixel SDX in the sub-display area SDA may be lower than the density of the main display pixel MDX in the main display area MDA. Accordingly, the luminance and resolution of the sub-display area SDA may be different from those of the main display area MDA.

Due to the transmission areas TA, the number of sub-emission areas SEA per unit area in the sub-display area SDA may be different from the number of main emission areas MEA per unit area in the main display area MDA. For example, the number of sub-emission areas SEA per unit area in the sub-display area SDA may be smaller than the number of main emission areas MEA per unit area in the main display area MDA.

In addition, a ratio of the area of the sub-emission areas SEA to the area of the sub-display area SDA may be different from a ratio of the area of the main emission areas MEA to the area of the main display area MDA, due to the transmission areas TA. For example, a ratio of the area of the sub-emission areas SEA to the area of the sub-display area SDA may be less than a ratio of the area of the main emission areas MEA to the area of the main display area MDA.

Multiple sub-pixel circuits SPC1, SPC2, and SPC3 located in the sub-display area SDA may each correspond to one sub-pixel electrode SAE1, SAE2, SAE3 and one sub-emission area SEA1, SEA2, SEA3. For example, the first sub-pixel circuit SPC1 may correspond to one first sub-pixel electrode SAE1 and be electrically connected to the first sub-pixel electrode SAE1 through a first contact hole CNT1. The second sub-pixel circuit SPC2 may correspond to one second sub-pixel electrode SAE2 and be electrically connected to the second sub-pixel electrode SAE2 through a second contact hole CNT2, and the third sub-pixel circuit SPC3 may correspond to one third sub-pixel electrode SAE3 and be electrically connected to the third sub-pixel electrode SAE3 through a third contact hole CNT3.

The light receiving element PD and the sensing pixel circuit that is electrically connected to the light receiving element PD and receives a sensing signal of the light receiving element PD may be further located in the sub-display area SDA. The sub-display area SDA may be an area where the light receiving elements PD and the sensing pixel circuits are arranged in specific arrangement. In the sub-display area SDA, each of the light receiving elements PD may constitute the sensing area PDA, and at least one sensing area PDA may constitute a sensing pixel (e.g., single sensing pixel) OPD.

The sensing pixel OPD may include at least one sensor electrode PE. The sensing area PDA of the sensing pixel OPD may overlap the transmission area TA. The sensing area PDA may be defined by the openings formed in the pixel defining film PDL (see FIG. 13) of the element layer EML to be described later. In some embodiments, as illustrated in FIG. 10, the density of the sensing pixel OPD may be less than the density of the sub-display pixel SDX to maintain the transmittance of the transmission area TA at a maximum.

A sensing pixel circuit PPC may be further located in the sub-display area SDA. The sensing pixel circuit PPC may correspond to the sensor electrode PE and the sensing area PDA. For example, the sensing pixel circuit PPC may correspond to the sensor electrode PE and be electrically connected to the sensor electrode PE through a fourth contact hole CNT4 and a fifth contact hole CNT5.

To increase the transmittance of the transmission area TA, the sensing pixel circuit PPC may overlap the sub-display pixel SDX. For example, the sensing pixel circuit PPC may overlap the sub-display pixel SDX without overlapping the transmission area TA. The sensing pixel circuit PPC may be electrically connected to the sensor electrode PE through a bridge electrode BRE.

In some embodiments, among the sub-display pixels SDX, the sub-display pixels SDX in which the sensing pixel circuit PPC is not located may include a dummy area DPC. The sensing pixel circuit PPC might not be located in the dummy area DPC.

A copy sensor electrode PPE may be further located in the sub-display area SDA. The copy sensor electrode PPE may be electrically connected to the sensor electrode PE through a bridge portion BAP. By including the copy sensor electrode PPE, the area of the sensing pixel OPD may be expanded, which improves sensing accuracy.

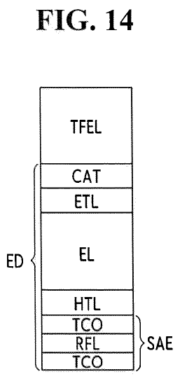

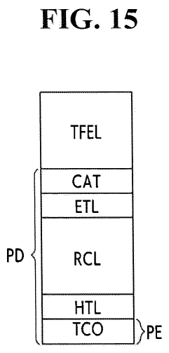

FIG. 13 is a cross-sectional view taken along line X2-X2′ in FIG. 12. FIG. 14 is a cross-sectional view illustrating a stacked structure of a light emitting element of a display device and an adjacent layer thereof according to an embodiment. FIG. 15 is a cross-sectional view illustrating a stacked structure of a light receiving element of a display device and an adjacent layer thereof according to an embodiment.

Referring to FIGS. 13 to 15, in addition to FIGS. 10 to 12, the display device 10 in the sub-display area SDA may include the sub-display pixel SDX and the sensing pixel OPD. The sub-display pixel SDX may include the first sub-pixel circuit SPC1, the second sub-pixel circuit SPC2, the third sub-pixel circuit SPC3, and the light emitting element ED located thereon. The sensing pixel OPD may include the sensing pixel circuit PPC and the light receiving element PD.

In some embodiments, each of the first sub-pixel circuit SPC1, the second sub-pixel circuit SPC2, and the third sub-pixel circuit SPC3 may include the third transistor ST3 and the sixth transistor ST6. The third transistor ST3 and the sixth transistor ST6 may have the same configuration as the third transistor ST3 and the sixth transistor ST6 illustrated in FIG. 6, respectively. The sensing pixel circuit PPC may include the second sensor transistor PT2, and the second sensor transistor PT2 may have the same configuration as the second sensor transistor PT2 illustrated in FIG. 8.

The third transistor ST3 may include the first electrode DE3, the second electrode SE3, the semiconductor region ACT3, and the gate electrode GE3. The first electrode DE3, the second electrode SE3, and the semiconductor region ACT3 of the third transistor ST3 may be located in the second active layer ACTL2. The gate electrode GE3 of the third transistor ST3 may be located in the third gate conductive layer GTL3.

The sixth transistor ST6 may include a first electrode DE6, a second electrode SE6, a semiconductor region ACT6, and a gate electrode GE6. The first electrode DE6, the second electrode SE6, and the semiconductor region ACT6 of the sixth transistor ST6 may be located in the first active layer ACTL1. The gate electrode GE6 of the sixth transistor ST6 may be located in the first gate conductive layer GTL1.

The second sensor transistor PT2 may include the first electrode PDE2, the second electrode PSE2, the semiconductor region PACT2, and the gate electrode PGE2. The first electrode PDE2, the second electrode PSE2, and the semiconductor region PACT2 of the second sensor transistor PT2 may be located in the second active layer ACTL2. The gate electrode PGE2 of the second sensor transistor PT2 may be located in the third gate conductive layer GTL3.

The lower conductive pattern BME may be further located below the sixth transistor ST6. The lower conductive pattern BME may be located in the lower conductive layer BML.

The light emitting element ED and the light receiving element PD may be located in the element layer EML.

The light emitting element ED of the first sub-emission area SEA1 may be electrically connected to the first sub-pixel circuit SPC1 through the first contact hole CNT1, the light emitting element ED of the second sub-emission area SEA2 may be electrically connected to the second sub-pixel circuit SPC2 through the second contact hole CNT2, and the light emitting element ED of the third sub-emission area SEA3 may be electrically connected to the third sub-pixel circuit SPC3 through the third contact hole CNT3.

The light receiving element PD of the sensing area PDA may be electrically connected to the sensing pixel circuit PPC through the fourth contact hole CNT4 and the fifth contact hole CNT5. For example, the sensor electrode PE of the light receiving element PD may be connected to the bridge electrode BRE through the fifth contact hole CNT5. The bridge electrode BRE may be connected to the sensing pixel circuit PPC through the fourth contact hole CNT4. In the drawing, the bridge electrode BRE is illustrated as being located in the second source metal layer SDL2, but is not necessarily limited thereto and may be located in the first source metal layer SDL1 (see FIG. 7).

The sensor electrode PE of the light receiving element PD, which is connected (e.g., directly connected) to the bridge electrode BRE through the fifth contact hole CNT5, may be connected to the copy sensor electrode PPE through the bridge portion BAP. The sensor electrode PE, the bridge portion BAP, and the copy sensor electrode PPE may be located in a same layer as a single, uninterrupted structure.

The sub-display area SDA may include a transmission area TA with high transmittance and a non-transmission area with low transmittance. The transmission area TA may be an area with high transmittance because the pixel circuit of the sub-display pixel SDX and the pixel circuit of the sensing pixel OPD are not located in the transmission area TA. For example, the first sub-pixel circuit SPC1, the second sub-pixel circuit SPC2, and the third sub-pixel circuit SPC3 of the sub-display pixel SDX, and the sensing pixel circuit PPC of the sensing pixel OPD might not overlap the transmission area TA and may be located in a non-transmission area.

In contrast, the light receiving element PD of the sensing pixel OPD may overlap the transmission area TA to improve sensing accuracy. For example, the sensor electrode PE and the copy sensor electrode PPE of the light receiving element PD may overlap the transmission area TA.

Accordingly, since the sensing pixel circuit PPC of the sensing pixel OPD is located in the non-transmission area and the light receiving element PD of the sensing pixel OPD is located in the transmission area TA, the bridge electrode BRE may be located across the non-transmission area and the transmission area TA to connect the sensing pixel circuit PPC of the sensing pixel OPD to the light receiving element PD of the sensing pixel OPD.

In some embodiments, the bridge electrode BRE, the sensor electrode PE, and the copy sensor electrode PPE may be located in the transmission area TA, and thus may be transparent electrodes. For example, the bridge electrode BRE, the sensor electrode PE, and the copy sensor electrode PPE may include a transparent conductive material (TCO) such as ITO or IZO. Through this, the transmittance of the transmission area TA may be improved.

For example, as illustrated in FIGS. 14 and 15, the light emitting element ED may include the light emitting layer EL between a sub-pixel electrode SAE and the common electrode CAT, and the sub-pixel electrode SAE of the light emitting element ED may be opaque by including a resonance structure in which a transparent conductive layer TCO and a reflective layer RFL are alternately stacked. In an embodiment, the reflective layer RFL may include a silver alloy (Ag alloy). On the other hand, the light receiving element PD may include the light receiving layer RCL between the sensor electrode PE and the common electrode CAT, and the sensor electrode PE of the light receiving element PD may be transparent by including the transparent conductive layer TCO.

In the display device 10 according to the embodiment, light may be sensed by the light receiving element PD embedded in the sub-display area SDA. Therefore, the optical sensor is embedded in the display panel 100 itself, so that an optical sensor such as a proximity sensor or a gesture sensor might not be provided as a separate, external optical device 700 under the sub-display area SDA. Accordingly, the manufacturing cost may be reduced, and the module of the display device 10 may become compact.

In some embodiments, separate from the optical sensor embedded in the display panel 100 itself, a separate, external optical device 700 may be located below the sub-display area SDA. For example, a sensor embedded in the sub-display area SDA of the display panel 100 may be used as a sensor having low sensing sensitivity, and the external optical device 700 located separately from the display panel 100 below the sub-display area SDA may be a sensor having high sensing sensitivity.

As a non-limiting example, the sensor embedded in the display panel 100 may be used as a proximity sensor or a gesture sensor, and the external optical device 700 provided separately below the display panel 100 may be used as a CMOS optical sensor or a high-resolution infrared sensor.

The external optical device 700 separately provided below the display panel 100 may perform sensing using incident light after passing through the transmission area TA, and the sensor embedded in the display panel 100 may perform sensing using light incident on the light receiving element PD located in the transmission area TA. For example, in a portion of the transmission area TA where the light receiving element PD is not located, light may pass through the transmission area TA and be incident on the external optical device 700, and in a portion of the transmission area TA where the light receiving element PD is located, light may be absorbed by the light receiving element PD.

In some embodiments, the range of wavelengths of light absorbed (or sensed) by the sensor embedded in the display panel 100 may be different from the range of wavelengths of light absorbed (or sensed) by the external optical device 700 separately provided below the display panel 100. For example, the sensor embedded in the display panel 100 may transmit light corresponding to the range of wavelengths of light absorbed (or sensed) by the external optical device 700 separately provided below the display panel 100. Also in the portion of the transmission area TA where the light receiving element PD is located, light of a certain wavelength range may be incident on the external optical device 700 separately provided below the display panel 100, and the incident light may be utilized by the external optical device 700.

For example, in the case where the external optical device 700 separately provided below the display panel 100 senses an infrared wavelength band within approximately 900 nm (i.e., a segment of the electromagnetic spectrum within the near-infrared (NIR) range that starts just beyond the visible light spectrum and extends up to about 900 nm, such as “in a range of about 700 nm to about 900 nm”), the sensor embedded in the display panel 100 may sense visible light or an infrared wavelength band within approximately 800 nm. In an embodiment, for a case in which the sensor embedded in the display panel 100 senses visible light, the light receiving layer RCL of the light receiving element PD may include a DCV5T-Me:C₆₀ material, and may include a BDP-OMe:C₆₀ material when infrared light within approximately 800 nm is sensed. For another example, for a case in which the external optical device 700 separately provided below the display panel 100 senses a visible light wavelength band, the sensor embedded in the display panel 100 may include at least one of a BDP-OMe:C₆₀ material or a QM1:C₆₀ material capable of sensing an infrared wavelength band.

According to embodiments, a display device 10 in a plan view may include a sub-display area SDA surrounded by a main display area MDA, where a light receiving element PD is disposed (or embedded) in the sub-display area SDA as opposed to being external to a display panel 100. By having the light receiving element PD in the display panel 100, an external optical device 700 may not be necessary, thereby reducing manufacturing costs and resulting in a more compact design. The sub-display area SDA may include sub-display pixels SDX, transmission areas TA, and sensing areas PDA that includes the light receiving elements PD. The light receiving elements PD may be disposed in a transmission area TA. In a thickness direction, the display device may include an element layer EML where the light emitting elements are disposed and a circuit layer TFTL where the sub-pixel circuits SPC and sub-emission areas SEA including light emitting elements ED are disposed. The light receiving elements PD may be arranged in either of the element layer EML or the circuit layer TFTL depending on the embodiment. As a result, the display area DA of the display device 10 is uninterrupted as light emitting pixels PX are arranged in the sub-display area SDA, while transparent regions TA capable of transmitting external light can include the light receiving elements PD.

Hereinafter, other embodiments of the display device according to an embodiment will be described. To the extent that an element is not described in detail with respect to the following embodiments, it may be understood that the element is at least similar to a corresponding element that has been described elsewhere within the present disclosure.

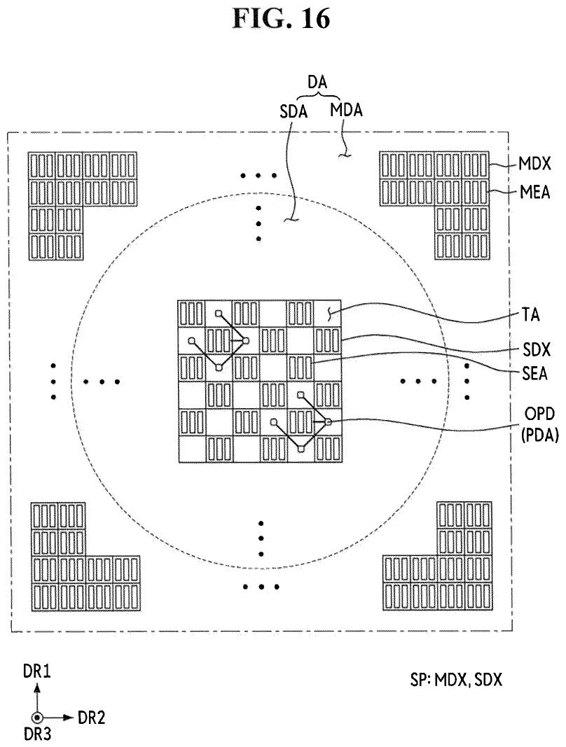

FIG. 16 is a plan view illustrating a display area of a display device according to an embodiment.

Referring to FIG. 16, the display device 10 according to the embodiment is different from the display device 10 according to the above-described embodiments in that the size of the sensing pixel OPD is smaller.

For example, the size of the sensing pixel OPD in the display device 10 according to the embodiment may be smaller than the size of the sensing pixel OPD in the display device 10 according to an embodiment described with reference to FIG. 10. Likewise, the width of the bridge electrode BRE in the display device 10 according to the embodiment may also be smaller than the width of the bridge electrode BRE in the display device 10 according to an embodiment described with reference to FIG. 10.

For example, in the display device 10 according to the embodiment, the size of a light receiving element (e.g., single light receiving element) PD of the sensing pixel OPD may be smaller than the size of one transmission area TA. In an embodiment, the planar area of a light receiving element (e.g., single light receiving element) PD of the sensing pixel OPD may be less than or substantially equal to 10% of the planar area of a transmission area TA.

Since the influence of the light receiving element PD on the transmittance of the transmission area TA is reduced, the light receiving element PD is not necessarily limited to a transparent material and may include an opaque material. For example, the bridge electrode BRE, the sensor electrode PE, and the copy sensor electrode PPE of the light receiving element PD according to the embodiment may include the same configuration as the stacked structure of the sub-pixel electrode SAE illustrated in FIG. 14 instead of the stacked structure of the sensor electrode PE illustrated in FIG. 15.

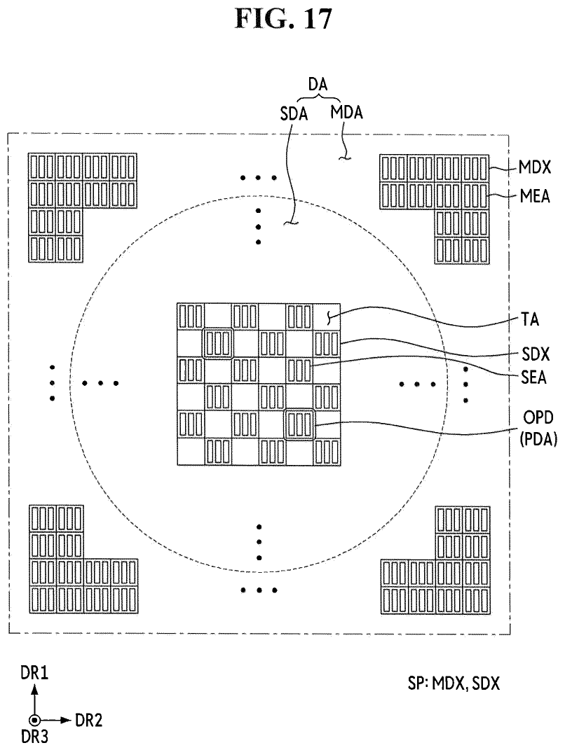

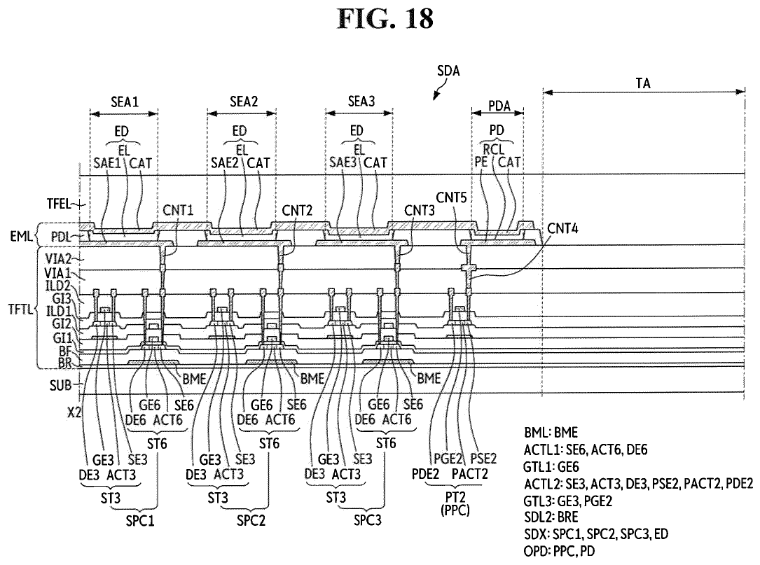

FIG. 17 is a plan view illustrating a display area of a display device according to an embodiment. FIG. 18 is a cross-sectional view illustrating a sub-display area of a display device according to the embodiment of FIG. 17.

Referring to FIGS. 17 and 18, the display device 10 according to the embodiment is different from the display device 10 according to the above-described embodiments in that the sensing pixel OPD is located adjacent to the sub-display pixel SDX.

For example, in the display device 10 according to the embodiment, the sensing pixels OPD may surround the sub-display pixel SDX. The sensing pixel OPD might not overlap the transmission area TA.

Since the influence of the sensing pixel OPD on the transmittance of the transmission area TA is reduced, the light receiving element PD of the sensing pixel OPD is not necessarily limited to a transparent material and may include an opaque material. For example, the bridge electrode BRE, the sensor electrode PE, and the copy sensor electrode PPE of the light receiving element PD according to the embodiment may include the same configuration as the stacked structure of the sub-pixel electrode SAE illustrated in FIG. 14 instead of the stacked structure of the sensor electrode PE illustrated in FIG. 15.

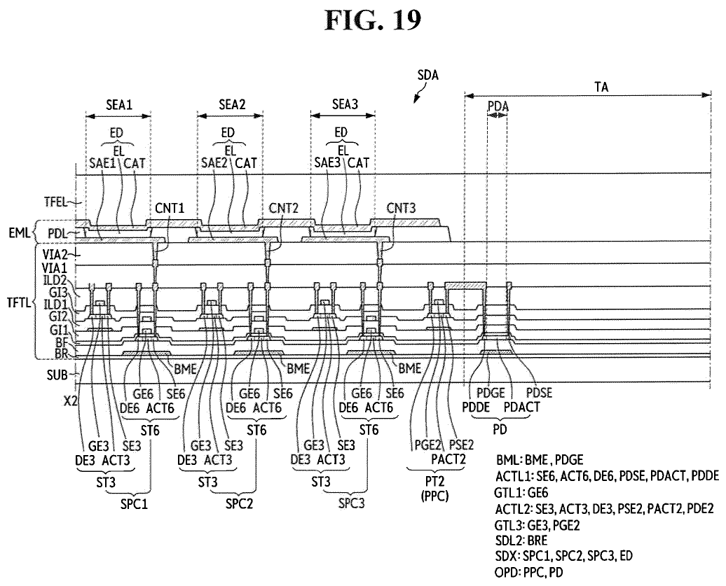

FIG. 19 is a cross-sectional view illustrating a sub-display area of a display device according to an embodiment.

Referring to FIG. 19, the display device 10 according to the embodiment is different from the display device 10 according to the above-described embodiments in that the light receiving element PD is located in the circuit layer TFTL rather than the element layer EML.

For example, the light receiving element PD may include a first electrode PDDE, a second electrode PDSE, a semiconductor region PDACT, and a gate electrode PDGE. The first electrode PDDE, the second electrode PDSE, and the semiconductor region PDACT of the light receiving element PD may be located in the first active layer ACTL1. The gate electrode PDGE of the light receiving element PD may be located in the lower conductive layer BML. The gate electrode PDGE of the light receiving element PD may have a bottom-gate structure in which the gate electrode PDGE is located below the semiconductor region PDACT to increase the amount of light received in a front direction (upward direction in the drawing).

The light receiving element PD may be a light sensing transistor. For example, the light receiving element PD may sense light by the photoconductive effect or the photogating effect of light incident on the semiconductor region PDACT.

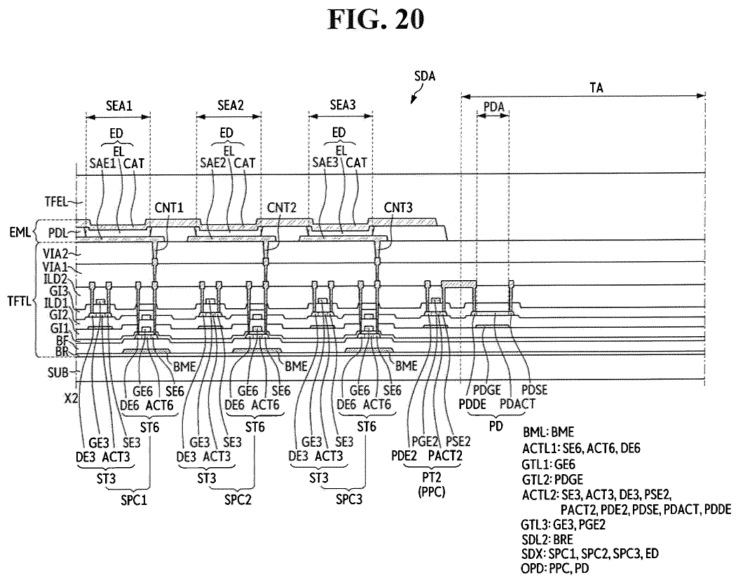

FIG. 20 is a cross-sectional view illustrating a sub-display area of a display device according to an embodiment.

Referring to FIG. 20, the display device 10 according to the embodiment is different from the display device 10 according to the above-described embodiments in that the light receiving element PD is located in the circuit layer TFTL rather than the element layer EML. The above is the same as the display device 10 according to an embodiment described with reference to FIG. 19 in that the light receiving element PD is located in the circuit layer TFTL rather than the element layer EML. However, in the display device 10 according to an embodiment described with reference to FIG. 19, the light receiving layer of the light receiving element PD is located in the first active layer ACTL1, whereas in the display device 10 according to the embodiment, the light receiving layer of the light receiving element PD is located in the second active layer ACTL2.

For example, the light receiving element PD may include the first electrode PDDE, the second electrode PDSE, the semiconductor region PDACT, and the gate electrode PDGE. The first electrode PDDE, the second electrode PDSE, and the semiconductor region PDACT of the light receiving element PD may be located in the second active layer ACTL2. The gate electrode PDGE of the light receiving element PD may be located in the second gate layer GTL2. The gate electrode PDGE of the light receiving element PD may have a bottom-gate structure in which the gate electrode PDGE is located below the semiconductor region PDACT to increase the amount of light received in a front direction (upward direction in the drawing).

The light receiving element PD may be a light sensing transistor. For example, the light receiving element PD may sense light by the photoconductive effect or the photogating effect of light incident on the semiconductor region PDACT.

According to embodiments, flexibility in the design of the light receiving element PD and in the sensing pixel OPD are possible. For example, the light sensing pixel OPD may be made smaller to occupy a small fraction of the transmission area TA, or may be formed to surround the sub-display pixel SDX so that the light receiving element PD can be comprised of opaque materials without severely impacting the transmissibility of the transmission areas TA. In another embodiment, the light receiving element PD may instead be arranged in the circuit layer TFTL instead of the element layer EML. Further, the light receiving element PD can be formed as part of the first active layer ACTL1 or the second active layer ACTL2 and can take the form of a diode or a transistor and still be in the scope of the disclosure. Other variations is to include an embedded light receiving element PD instead of or in addition to an external optical device 700 and still be in the scope of the disclosure.

The display device 10 according to the above-described embodiments may be applied to various electronic devices 1. An electronic device 1 according to an embodiment may include the above-described display device 10, and may further include, in addition to the display device 10, a module or device having other additional functions.

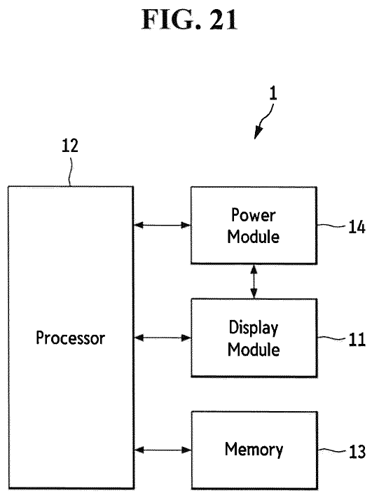

FIG. 21 is a block diagram of an electronic device according to an embodiment.

Referring to FIG. 21, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 1.

At least one of the components of the electronic device 1 described above may be included in the display device 10 according to the embodiments described above. Further, some of individual modules functionally included in a module may be included in the display device 10 and some others may be provided separately from the display device 10. For example, the display device 10 may include the display module 11, and the processor 12, the memory 13, and the power module 14 may be provided in the form of other devices in the electronic device 1 other than the display device 10.

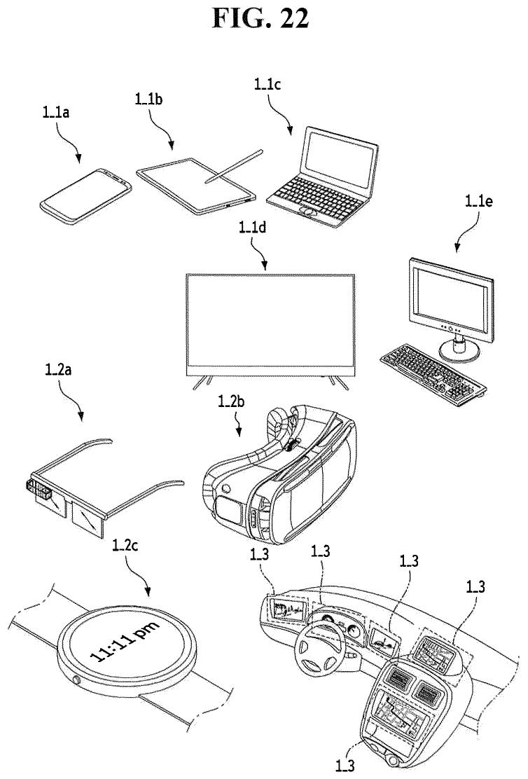

FIG. 22 is schematic views of electronic devices according to various embodiments.

Referring to FIG. 22, various electronic devices 1 to which the display device 10 according to embodiments is applied may include not only an image display electronic device 1 such as a smartphone 1_1a, a tablet 1_1b, a laptop 1_1c, a TV 1_1d, and a monitor 1_1e, but also a wearable electronic device 1 including a display module, such as smart glasses 1_2a, a head mounted display 1_2b, a smart watch 1_2c, or the like, a vehicle electronic device 1_3 including a display module, such as a center fascia, and a dashboard of an automobile, a center information display (CID) placed on the dashboard, a room mirror display, and the like.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a first display area comprising a first light emitting pixel comprising a first light emitting pixel circuit and a first light emitting element;
a second display area surrounded by the first display area, the second display area comprising a second light emitting pixel comprising a second light emitting pixel circuit and a second light emitting element, a transmission area disposed on a side of the second light emitting pixel, and a sensing pixel comprising a sensing pixel circuit and at least one light receiving element;
a substrate;
a circuit layer disposed on the substrate, the circuit layer comprising the first light emitting pixel circuit, the second light emitting pixel circuit, and the sensing pixel circuit are disposed; and
an element layer comprising the first light emitting element and the second light emitting element, wherein
the at least one light receiving element is disposed in at least one of the circuit layer or the element layer,
the at least one light receiving element overlaps the transmission area in a plan view, and
the sensing pixel circuit of the sensing pixel does not overlap the transmission area.

2. The display device of claim 1, wherein each of the at least one light receiving element comprises:
a sensor electrode;
a light receiving layer disposed on the sensor electrode; and
a common electrode disposed on the light receiving layer, wherein
the sensor electrode, the light receiving layer, and the common electrode each comprise a transparent material.

3. The display device of claim 2, wherein the light receiving layer comprises at least one of DCV5T-Me:C₆₀, BDP-OMe:C₆₀, or QM1:C₆₀.

4. The display device of claim 2, wherein
the first light emitting element and the second light emitting element each comprises:
a pixel electrode;
a light emitting layer disposed on the pixel electrode; and
the common electrode disposed on the light emitting layer, and
the pixel electrode comprises an opaque electrode.

5. The display device of claim 4, wherein
the sensor electrode comprises a transparent conductive layer (TCO), and
the pixel electrode comprises:
a transparent conductive layer (TCO); and
a reflective layer.

6. The display device of claim 5, wherein
the transparent conductive layer comprises at least one of ITO or IZO, and
the reflective layer comprises a silver alloy.

7. The display device of claim 1, wherein
each of the at least one light receiving element comprises a first light receiving element comprising a first sensor electrode, and
the first sensor electrode is electrically connected to the sensing pixel circuit through a bridge electrode disposed in a different layer from the first sensor electrode.

8. The display device of claim 7, wherein
the first sensor electrode and the bridge electrode are connected by a contact hole penetrating an insulating film, and
the contact hole is disposed in the transmission area.

9. The display device of claim 7, wherein
the bridge electrode overlaps the transmission area in a plan view, and
the first sensor electrode and the bridge electrode each comprise transparent electrodes.

10. The display device of claim 7, wherein
each of the at least one light receiving element further comprises a second light receiving element comprising a second sensor electrode,
the second sensor electrode is connected to the first sensor electrode through a bridge portion, and
the first sensor electrode, the second sensor electrode, and the bridge portion are disposed in a same layer.

11. The display device of claim 1, wherein a density of the first light emitting pixel in the first display area is greater than a density of the second light emitting pixel in the second display area.

12. The display device of claim 1, wherein a density of the second light emitting pixel in the second display area is greater than a density of the sensing pixel in the second display area.

13. The display device of claim 1, further comprising:
a non-display area disposed external to the first display area;
a display driving circuit disposed in the non-display area; and
a read-out line intersecting the second display area and the non-display area, wherein
the sensing pixel is connected to the display driving circuit through the read-out line.

14. The display device of claim 1, wherein
the circuit layer comprises a first active layer and a second active layer in which semiconductor regions of respective transistors of the first light emitting pixel circuit and the second light emitting pixel circuit are disposed,
each of the at least one light receiving element is a light sensing transistor disposed in the circuit layer and comprising a semiconductor region that receives light, and
the semiconductor region of the light sensing transistor of each of the at least one light receiving element is disposed in at least one of the first active layer and the second active layer.

15. The display device of claim 1, further comprising a touch sensing layer disposed on the element layer.

16. The display device of claim 15, further comprising a color filter layer disposed on the touch sensing layer.

17. The display device of claim 1, wherein the second light emitting pixel and the transmission area are alternately disposed in the second display area.

18. The display device of claim 17, wherein the at least one light receiving element comprises a plurality of light receiving elements that surround the second light emitting pixel.

19. The display device of claim 1, wherein
the second display area further comprises a dummy area in an area other than the transmission area, and
the second light emitting pixel and the sensing pixel circuit are not disposed in the dummy area.

20. An electronic device comprising:
a display device configured to an image;
a processor configured to provide an image driving signal to the display device; and
a power module configured to supply power to the display device and the processor, wherein the display device comprises:
a first display area comprising a first light emitting pixel comprising a first light emitting pixel circuit and a first light emitting element;
a second display area surrounded by the first display area, the second display area comprising a second light emitting pixel comprising a second light emitting pixel circuit and a second light emitting element, a transmission area disposed on a side of the second light emitting pixel, and a sensing pixel comprising a sensing pixel circuit and a light receiving element;
a substrate;
a circuit layer disposed on the substrate, the circuit layer comprising the first light emitting pixel circuit, the second light emitting pixel circuit, and the sensing pixel circuit; and
an element layer comprising the first light emitting element and the second light emitting element, wherein
the light receiving element is disposed in at least one of the circuit layer or the element layer,
the light receiving element of the sensing pixel overlaps the transmission area in a plan view, and
the sensing pixel circuit of the sensing pixel does not overlap the transmission area.
